(19) United States
(12) Patent Application Publication
(10) Pub. No.: US 2026/0190823 A1
(43) Pub. Date: Jul. 2, 2026

(54) Light Emitting Display Apparatus

(71) Applicant: LG Display Co., Ltd., Seoul (KR)

(72) Inventors: Hyeonjeong Shin, Paju-si (KR); JiYoung Ahn, Paju-si (KR); KyungYun Kang, Paju-si (KR); AhnKi Kim, Paju-si (KR)

(21) Appl. No.: 19/222,551

(22) Filed: May 29, 2025

(30) Foreign Application Priority Data
Dec. 31, 2024 (KR) 10-2024-0202227

(51) Int. Cl. H10K 59/80; H10K 59/35

(52) U.S. Cl. CPC H10K 59/8792; H10K 59/351

(57) ABSTRACT

A light emitting display apparatus can comprise a substrate including a plurality of unit pixels, a buffer layer on the substrate, a planarization layer on the buffer layer, a light emitting device layer configured on the planarization layer and including a first electrode, a light emitting layer, and a second electrode, and a light absorbing layer between the light emitting layer and the second electrode. The light absorbing layer absorbs external light incident on the light emitting display apparatus.

### CROSS-REFERENCE TO RELATED APPLICATION

This application claims the benefit of the Republic of Korea Patent Application No. 10-2024-0202227 filed on Dec. 31, 2024, which is hereby incorporated by reference in its entirety.

### BACKGROUND

### Field of Technology

The present disclosure relates to a light emitting display apparatus.

### Discussion of the Related Art

Light-emitting display devices are self-luminous display devices that do not require a separate light source, unlike liquid crystal display devices, so they can be manufactured in a lightweight and thin manner. In addition, light-emitting display devices are in the spotlight as next-generation display devices because they are advantageous in terms of power consumption by driving low voltage and have excellent color arrangement, response speed, viewing angle, and contrast ratio.

The light emitting display apparatus displays an image through light emission of a light emitting device layer including a light emitting device interposed between two electrodes. In this case, light generated according to light emission of the light emitting device is emitted to the outside through a substrate or the like.

Meanwhile, the light emitting display apparatus may have deteriorated visibility due to reflection by external light coming from outside of the light emitting display apparatus.

### SUMMARY

The inventors of this specification recognized the above-mentioned problems and invented a light emitting display apparatus with a new structure capable of reducing reflection by external light through various experiments.

An embodiment of the present disclosure is directed to providing a light emitting display apparatus capable of reducing reflection by external light and improving reliability.

Additional advantages and features of the disclosure will be set forth in portion in the description which follows and in portion will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other embodiments of the inventive concepts, as embodied and broadly described herein, a light emitting display apparatus can comprise a substrate including a plurality of unit pixels, a buffer layer on the substrate, a planarization layer on the buffer layer, a light emitting device layer on the planarization layer and including a first electrode, a light emitting layer on the first electrode, and a second electrode on the light emitting layer, and a light absorbing layer between the light emitting layer and the second electrode, the light absorbing layer absorbing external light incident on the light emitting display apparatus.

According to one embodiment, a display device comprises: a substrate including a unit pixel comprising a first sub-pixel that emits light of a first color and a second sub-pixel that emits light of a second color; a buffer layer on the substrate; a planarization layer over the first color filter; a light emitting device layer on the planarization layer, the light emitting device layer including a first electrode, a light emitting layer on the first electrode, and a second electrode on the light emitting layer; and a light absorbing layer between the light emitting layer and the second electrode in at least the second sub-pixel, the light absorbing layer having a refractive index that is different from a refractive index of the second electrode.

According to one or more embodiments of the present disclosure, the light emitting display apparatus includes the light absorbing layer, and thus, reflection by external light may be improved, and reliability of the light emitting display apparatus may be improved.

According to one or more embodiments of the present disclosure, the light emitting display apparatus includes the light absorbing layer and a color control layer. Therefore, in the white sub-pixel, the reflection spectrum of light that is partially absorbed by the light absorbing layer, reflected by the cathode electrode, and emitted to the outside can be controlled.

According to one or more embodiments of the present disclosure, the light emitting display apparatus includes the light absorbing layer, the color control layer, and an auxiliary pattern portion. Therefore, low reflection can be implemented in the white sub-pixel, and the luminance of the light emitting display apparatus can be improved.

According to one or more embodiments of the present disclosure, the light emitting display apparatus includes at least one of the light absorbing layer, the low reflective layer, the auxiliary pattern portion, and the color control layer. Therefore, low reflection of the light emitting display apparatus can be implemented, a manufacturing process can be unified, and there is an effect of Uni materialization.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a portion of this application, illustrate embodiments of the disclosure and together with the description serve to explain the principle of the disclosure.

FIG. 1 is a diagram illustrating a light emitting display apparatus according to an embodiment of the present disclosure.

FIG. 2 is a diagram illustrating an arrangement structure of pixels illustrated in FIG. 1 according to an embodiment of the present disclosure.

FIG. 3 is a cross-sectional view along line I-I′ shown in FIG. 2 according to an embodiment of the present disclosure.

FIG. 4 is a cross-sectional view along line I-I′ shown in FIG. 2 according to another embodiment of the present disclosure.

FIG. 5 is a cross-sectional view along line I-I′ shown in FIG. 2 according to another embodiment of the present disclosure.

FIG. 6 is a cross-sectional view along line I-I′ shown in FIG. 2 according to another embodiment of the present disclosure.

FIG. 7 is a cross-sectional view along line I-I′ shown in FIG. 2 according to another embodiment of the present disclosure.

FIG. 8 is a diagram illustrating an arrangement structure of pixels illustrated in FIG. 1 according to another embodiment of the present disclosure.

FIG. 9 is a cross-sectional view along line II-II′ shown in FIG. 8 according to an embodiment of the present disclosure.

FIG. 10 is a cross-sectional view along line II-II′ shown in FIG. 8 according to another embodiment of the present disclosure.

FIG. 11 is a cross-sectional view along line II-II′ shown in FIG. 8 according to another embodiment of the present disclosure.

FIG. 12 is a cross-sectional view along line II-II′ shown in FIG. 8 according to another embodiment of the present disclosure.

FIG. 13 is a diagram illustrating an arrangement structure of pixels illustrated in FIG. 1 according to another embodiment of the present disclosure.

FIG. 14 is a diagram illustrating an arrangement structure of pixels illustrated in FIG. 1 according to another embodiment of the present disclosure.

FIG. 15 is a cross-sectional view along line III-III′ shown in FIG. 14 according to an embodiment of the present disclosure.

FIG. 16 is a cross-sectional view along line III-III′ shown in FIG. 14 according to another embodiment of the present disclosure.

FIG. 17 is a diagram illustrating an arrangement structure of pixels illustrated in FIG. 1 according to another embodiment of the present disclosure.

FIG. 18 is a cross-sectional view along line IV-IV′ shown in FIG. 17 according to an embodiment of the present disclosure.

FIG. 19 is a cross-sectional view along line IV-IV′ shown in FIG. 17 according to another embodiment of the present disclosure.

FIG. 20 is a diagram illustrating an arrangement structure of pixels illustrated in FIG. 1 according to another embodiment of the present disclosure.

FIG. 21 is a cross-sectional view along line V-V′ shown in FIG. 20 according to an embodiment of the resent disclosure.

FIG. 22 is a diagram showing reflectance according to experimental example and embodiment of the present disclosure.

FIGS. 23A to 23D are diagrams showing refractive indices according to the deposition rate of the light absorbing layer.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like portions.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like devices throughout. In the following description, when the detailed description of the relevant known function or configuration is determined to unnecessarily obscure the important point of the present disclosure, the detailed description will be omitted. When “comprise,” “have,” and “include” described in the present disclosure are used, another portion can be added unless “only” is used. The terms of a singular form can include plural forms unless referred to the contrary.

In construing a device, the device is construed as including an error or tolerance range although there is no explicit description of such an error or tolerance range.

In describing a position relationship, for example, when a position relation between two portions is described as, for example, “on,” “over,” “under,” and “next,” one or more other portions can be disposed between the two portions unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various devices, these devices should not be limited by these terms. These terms are only used to distinguish one device from another and may not define order of sequence. For example, a first device could be termed a second device, and, similarly, a second device could be termed a first device, without departing from the scope of the present disclosure.

In describing devices of the present disclosure, the terms “first,” “second,” “A,” “B,” “(a),” “(b),” etc. can be used. These terms are intended to identify the corresponding devices from the other devices, and basis, order, or number of the corresponding devices should not be limited by these terms. The expression that a device is “connected,” “coupled,” or “adhered” to another device or layer should be understood the device or layer cannot only be directly connected or adhered to another device or layer, but also be indirectly connected or adhered to another device or layer with one or more intervening devices or layers “disposed,” or “interposed” between the devices or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Also, the term “can” used herein includes all meanings and definitions of the word “may”.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, embodiments of the present disclosure will be described in detail with reference to the accompanying drawings.

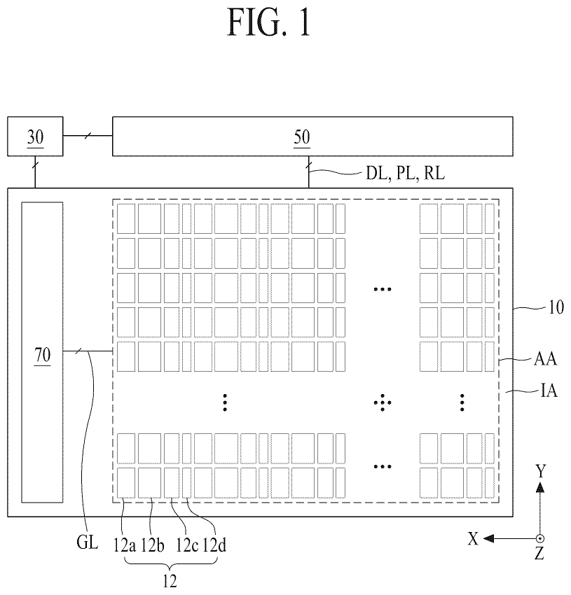

FIG. 1 is a diagram illustrating a light emitting display apparatus according to an embodiment of the present disclosure.

Referring to FIG. 1, a light emitting display apparatus according to an embodiment of the present disclosure may include a display panel 10, a control circuit 30, a data driving circuit 50, and a gate driving circuit 70.

The display panel 10 may include a display area AA (or an active area) defined on a substrate, and a non-display area IA (or an inactive area) surrounding the display area AA.

The display area AA may include a plurality of sub-pixels 12a, 12b, 12c, and 12d disposed in an area defined by n gate lines GL and m data lines DL.

Each of the n gate lines GL may extend long in the first direction X and may be spaced apart from each other in the second direction Y crossing the first direction X.

Each of the m data lines DL may extend long along the second direction Y and may be spaced apart from each other along the first direction X.

The display area AA may further include a plurality of pixel driving voltage lines PL and a plurality of reference voltage lines RL disposed in parallel with the data line DL. Each of the n gate lines GL may include an intersection portion crossing each of the m data lines DL, the plurality of pixel driving voltage lines PL, and the plurality of reference voltage lines RL. The intersection portion of each of the n gate lines GL may include at least one slit or opening portion for minimizing an overlapping area with other lines.

Each of the plurality of sub-pixels 12a, 12b, 12c, and 12d may display a color image corresponding to a gate signal supplied from the adjacent gate line GL and a data voltage supplied from the adjacent data line DL. For example, each of the plurality of sub-pixels 12a, 12b, 12c, and 12d may be arranged adjacent to each other in the longitudinal direction X of the gate line GL.

According to an embodiment of the present disclosure, each of the plurality of sub-pixels 12a, 12b, 12c, and 12d may include a pixel circuit disposed in a circuit area (or a non-emission area) of the sub-pixel area, and a light emitting device layer disposed in an opening area (or a light emitting area) of the sub-pixel area and electrically connected to the pixel circuit. For example, the pixel circuit may include at least two transistors and at least one capacitor. The light emitting device layer may include a self-emission device that displays an image by emitting light by a data signal provided from the pixel circuit.

Each of the plurality of sub-pixels 12a, 12b, 12c, and 12d may be defined as an area of a minimum unit in which actual light is emitted. For example, at least four pixels adjacent to each other may be a unit pixel 12 for color display of an image.

The unit pixel 12 according to an example may include first to fourth sub-pixels 12a, 12b, 12c, and 12d arranged adjacent to each other along a length direction of the gate line GL. For example, the first sub-pixel 12a may be a red sub-pixel or a first color sub-pixel that emits red light. The second sub-pixel 12b may be a white sub-pixel or a second color sub-pixel that emits white light. The third sub-pixel 12c may be a blue sub-pixel or a third color sub-pixel that emits blue light. The fourth sub-pixel 12d may be a green sub-pixel or a fourth color sub-pixel that emits green light.

The light emitting device layers disposed in each of the first to fourth sub-pixels 12a, 12b, 12c, and 12d may emit different color light individually or may all emit white light. For example, when each of the light emitting device layers of the first to fourth sub-pixels 12a, 12b, 12c, and 12d emits white light in common, each of the first, third, and fourth sub-pixels 12a, 12c, and 12d may include color filters (or different wavelength conversion members) that convert white light into different color light. For example, the second sub-pixel 12b according to an embodiment may not include a color filter since the second sub-pixel 12b is configured to emit white light. According to another embodiment, at least a partial region of the second sub-pixel 12b may include the same color filter as any one of the first, third, and fourth sub-pixels 12a, 12c, and 12d.

The control circuit 30 may generate a pixel-specific data signal corresponding to each of a plurality of sub-pixels 12a, 12b, 12c, and 12d based on an image signal. The control circuit 30 according to an embodiment may extract white pixel data based on an image signal, that is, red input data, green input data, and blue input data of each unit pixel 12. The control circuit 30 may calculate red pixel data, green pixel data, and blue pixel data by reflecting offset data based on the extracted white pixel data onto the red input data, green input data, and blue input data, respectively. The control circuit 30 can arrange the calculated red pixel data, green pixel data, blue pixel data, and white pixel data appropriately according to the pixel array structure and supply them to the data driving circuit 50. For example, the control circuit 30 may convert input data of red, green, and blue into four color data of red, green, blue, and white.

The control circuit 30 may drive the gate driving circuit 50 and the data driving circuit 70 in a display mode or a sensing mode. The control circuit 30 may generate each of a data control signal and a gate control signal for driving each of the gate driving circuit 50 and the data driving circuit 70 in a display mode or a sensing mode based on the timing signal. The control circuit 30 may provide the data control signal to the data driving circuit 50 and may provide the gate control signal to the gate driving circuit 70. For example, the sensing mode (or external compensation driving) may be performed during the inspection process before the shipment of the light-emitting display device, at the initial drive of the display panel 10, when the power of the light emitting display apparatus is turned on (power on), when the power of the light emitting display apparatus is turned off (power off), or after long-term driving of the display panel 10 followed by power off (power off), either in real-time or periodically during the blank period of the set frame.

The control circuit 30 may store pixel-specific sensing data provided from the data driving circuit 50 in the storage circuit according to the sensing mode. In the display mode, the control circuit 30 may correct pixel data to be supplied to each of the sub-pixels 12a, 12b, 12c, and 12d based on sensing data stored in the storage circuit, and provide the corrected pixel data to the data driving circuit 50. For example, the sensing data for each pixel may include change information over time of each of the driving transistor and the light emitting device. Accordingly, in the sensing mode, the control circuit 30 senses a characteristic value (e.g., a threshold voltage or mobility) of the driving transistor disposed in each of the sub-pixels 12a, 12b, 12c, and 12d, and correct pixel data to be supplied to each of the sub-pixels 12a, 12b, 12c, and 12d based on the sensed value. Accordingly, image quality degradation caused by a deviation of characteristic values of the driving transistor in a plurality of sub-pixels may be minimized or prevented.

The data driving circuit 50 may be individually connected to each of the m data lines DL disposed on the display panel 10. The data driving circuit 50 may receive pixel-specific data signals and data control signals provided from the control circuit 30, as well as a plurality of reference gamma voltages provided from the power circuit.

In the display mode, the data driving circuit 50 may convert the pixel-specific data signals in digital form into pixel-specific data voltages in analog form using the data control signals and a plurality of reference gamma voltages. The data driving circuit 50 supplies the converted pixel-specific data voltages to the corresponding data lines DL and generates reference voltages synchronized with the data voltages, which are then supplied to a plurality of reference voltage lines RL.

In the sensing mode, the data driving circuit 50 may convert a digital sensing data signal into a sensing data voltage based on the data control signal and a plurality of reference gamma voltages, and supply the same to the corresponding sub-pixels 12a, 12b, 12c, and 12d through the corresponding data line DL. The data driving circuit 50 may sense characteristic values of driving transistors disposed in the corresponding sub-pixels 12a, 12b, 12c, and 12d through each of the plurality of reference voltage lines RL, and provide the sensed sensing data for each pixel to the control circuit 30. For example, the data driving circuit 50 may sequentially sense the first to fourth sub-pixels 12a, 12b, 12c, and 12d constituting the unit pixel 12.

The gate driving circuit 70 may be individually connected to each of the n gate lines GL provided in the pixel array unit. The gate driving circuit 70 may generate a gate signal according to a predetermined order based on the gate control signal supplied from the control circuit 30, and supply the gate signal to the corresponding gate line GL.

According to an embodiment of the present disclosure, the gate driving circuit 70 may be integrated at one side edge and/or both side edges of the substrate according to the manufacturing process of the thin-film transistor, and may be connected one-to-one with a plurality of gate lines GL. According to another embodiment of the present disclosure, the gate driving circuit 70 is configured as an integrated circuit and may be mounted on the substrate or on a flexible circuit film, and may be connected one-to-one with a plurality of gate lines GL.

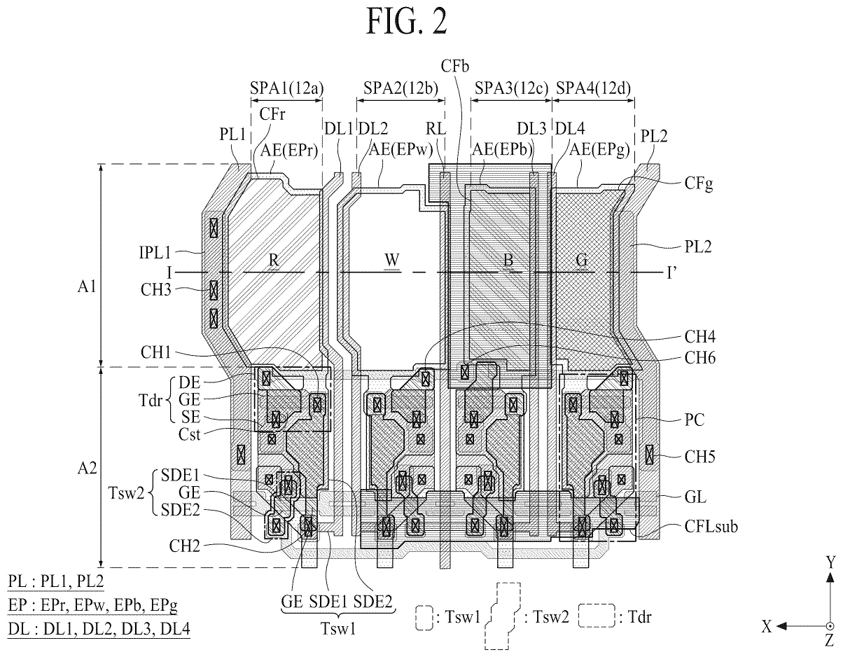

FIG. 2 is a diagram illustrating an arrangement structure of pixels illustrated in FIG. 1 according to an embodiment of the present disclosure.

Referring to FIG. 2, the light emitting display apparatus 10 according to an embodiment of the present disclosure may include a plurality of unit pixels 12. Any one of a plurality of unit pixels 12 may include a plurality of sub-pixel areas SPA1 to SPA4 disposed along the first direction X and the second direction Y crossing the first direction Y, and a plurality of metal lines PL, DL, and RL extending lengthwise along the second direction Y and disposed in a plurality of sub-pixel areas SPA1 to SPA4.

Each of a plurality of sub-pixel areas SPA1 to SPA4 or a plurality of sub-pixels 12a, 12b, 12c, and 12d may overlap all or portion of at least one metal line adjacent in the first direction X among a plurality of metal lines PL, DL, and RL, or may be disposed between the adjacent metal lines PL, DL, and RL. A plurality of sub-pixel areas SPA1 to SPA4 or a plurality of sub-pixels 12a, 12b, 12c, and 12d may have different sizes. In the following description, the sizes of the sub-pixel areas SPA1 to SPA4 or a plurality of sub-pixels 12a, 12b, 12c, and 12d may be understood as an area of the sub-pixel areas SPA1 to SPA4 or a plurality of sub-pixels 12a, 12b, 12c, and 12d. Also, the sub-pixel areas SPA1 to SPA4 may be understood as sub-pixels 12a, 12b, 12c, and 12d.

Each of the plurality of metal lines PL, DL, and RL disposed in the unit pixel 12 may include pixel driving voltage lines PL1 and PL2, a plurality of data lines DL1, DL2, DL3, and DL4, and a reference voltage line RL.

Among a plurality of sub-pixel areas SPA1 to SPA4, the first sub-pixel area SPA1 may be disposed between a first data line DL1 among a plurality of data lines and the first pixel driving voltage line PL1 among a plurality of pixel driving voltage lines PL. For example, the first data line DL1 may be a first color data line or a red data line. The first pixel driving voltage line PL1 may be an odd-numbered pixel driving voltage line among a plurality of pixel driving voltage lines PL. For example, based on the first sub-pixel area SPA1, the first pixel driving voltage line PL1 may be a first metal line, and the first data line DL1 may be a second metal line.

Among a plurality of sub-pixel areas SPA1 to SPA4, the second sub-pixel area SPA2 may be disposed between the second data line DL2 among the plurality of data lines and a reference voltage line RL. For example, the second data line DL2 may be a second color data line or a white data line. The first data line DL1 and the second data line DL2 may be disposed adjacent and parallel to each other. For example, based on the second sub-pixel area SPA2, the second data line DL2 may be a first metal line, and the reference voltage line RL may be a second metal line.

Among a plurality of sub-pixel areas SPA1 to SPA4, the third sub-pixel area SPA3 may be disposed between the third data line DL3 among the plurality of data lines and the reference voltage line RL. For example, the third data line DL3 may be a third color data line or a blue data line. For example, based on the third sub-pixel area SPA3, the reference voltage line RL may be a first metal line, and the third data line DL3 may be a second metal line.

Among the plurality of sub-pixel areas SPA1 to SPA4, the fourth sub-pixel area SPA4 may be disposed between the fourth data line DL4 among the plurality of data lines and the second pixel driving voltage line PL2 among the plurality of pixel driving voltage lines PL. For example, the fourth data line DL4 may be a fourth color data line or a green data line. The second pixel driving voltage line PL2 may be an even-numbered pixel driving voltage line among the plurality of pixel driving voltage lines PL. The third data line DL3 and the fourth data line DL4 may be disposed adjacent and parallel to each other. For example, based on the fourth sub-pixel area SPA4, the fourth data line DL4 may be a first metal line, and the second pixel driving voltage line PL2 may be a second metal line.

Each of the plurality of sub-pixel areas SPA1 to SPA4 may be divided into a first area A1 and a second area A2 based on the second direction Y.

The first area A1 (or light emitting area) may be disposed on an upper side with respect to the second direction Y and may be non-overlapping with the gate line GL. The first area A1 of each of the plurality of sub-pixel areas SPA1 to SPA4 may have different sizes.

The plurality of sub-pixel areas SPA1 to SPA4 may include a plurality of light emitting portions EP disposed in the first area A (or light emitting area). Each of a plurality of light emitting portions EP may be configured to correspond to each of the plurality of sub-pixel areas SPA1 to SPA4. The plurality of light emitting portion EP may include a first light emitting portion EPr, a second light emitting portion EPw, a third light emitting portion EPb, and a fourth light emitting portion EPg. The first light emitting portion EPr may be disposed in the first sub-pixel SPA1 and the second light emitting portion EPw may be disposed in the second sub-pixel SPA2. The third light emitting portion EPb may be disposed in the third sub-pixel SPA3 and the fourth light emitting portion EPg may be disposed in the fourth sub-pixel SPA4. Each light emitting device layer disposed in the light emitting portion EP of each of a plurality of sub-pixel areas SPA1 to SPA4 may include a first electrode AE, a light emitting layer EL, and a second electrode.

The second area A2 (or circuit area) may be disposed at a lower side with respect to the second direction Y and may overlap the gate line GL. The second area A2 of each of the plurality of sub-pixel areas SPA1 to SPA4 may have substantially the same size, but is not limited thereto.

Each of the plurality of sub-pixel areas SPA1 to SPA4 may include a pixel circuit PC disposed in the second area A2 (or a circuit area).

The pixel circuit PC of each of the plurality of sub-pixel areas SPA1 to SPA4 may include a gate line GL, a pixel driving voltage line PL, four data lines DL1, DL2, DL3, and DL4, and the reference voltage line RL.

The gate line GL may be disposed in one side area spaced apart from the first area A1 among the second areas A2 of the plurality of sub-pixel areas SPA1 to SPA4.

The pixel circuit PC of each of a plurality of sub-pixel areas SPA1 to SPA4 may include a first switching transistor Tsw1, a second switching transistor Tsw2, a driving transistor Tdr, and a storage capacitor Cst. Each of the transistors Tsw1, Tsw2, and Tdr of the pixel circuit PC may be formed of a thin film transistor TFT. For example, at least one of the thin film transistors Tsw1, Tsw2, and Tdr may be an a-Si TFT, a poly-Si TFT, an oxide TFT, or an organic TFT. For example, in the pixel circuit PC, some of the first switching transistor Tsw1, the second switching transistor Tsw2, and the driving transistor Tdr may be thin film transistors including a semiconductor layer (or an active layer) made of low-temperature poly-Si (LTPS) having excellent response characteristics. For example, except for some of the first switching transistor Tsw1, the second switching transistor Tsw2, and the driving transistor Tdr, the remaining transistors may be thin film transistors including a semiconductor layer (or active layer) made of oxide having excellent off-current characteristics.

The first switching transistor Tsw1 may include a gate electrode GE, a first source/drain electrode SDE1 connected to the adjacent data line DL, and a second source/drain electrode SDE2 connected to the gate electrode GE of the driving transistor Tdr through a first contact hole CH1. The gate electrode GE of the first switching transistor Tsw1 may be configured to be adjacent to the gate line GL. For example, the gate electrode GE of the first switching transistor Tsw1 may be a partial area of the gate line GL.

The first switching transistor Tsw1 may be turned on according to the first gate signal supplied to the gate line GL to supply the data voltage supplied from the adjacent data line DL to the gate electrode GE of the driving transistor Tdr.

For example, the first source/drain electrode SDE1 of the first switching transistor Tsw1 disposed in the first sub-pixel area SPA1 may be a protruding area protruding from one side of the first data line DL1. For example, the first source/drain electrode SDE1 of the first switching transistor Tsw1 disposed in the second sub-pixel area SPA2 may be a protruding area protruding from one side of the second data line DL2. For example, the first source/drain electrode SDE1 of the first switching transistor Tsw1 disposed in the third sub-pixel area SPA3 may be a protruding area protruding from one side of the first data line DL3. For example, the first source/drain electrode SDE1 of the first switching transistor Tsw1 disposed in the fourth sub-pixel area SPA4 may be a protruding area protruding from one side of the fourth data line DL4.

The second switching transistor Tsw2 may include a gate electrode GE connected to the gate line GL, a first source/drain electrode SDE1 connected to the source electrode of the driving transistor Tdr, and a second source/drain electrode SDE2 connected to the adjacent reference voltage line RL. In the display mode, the second switching transistor Tsw2 may supply a reference voltage supplied to an adjacent reference voltage line RL to the source electrode SE of the driving transistor Tdr according to a gate signal supplied to the gate line GLb. Also, in the sensing mode, the second switching transistor Tsw2 may be turned on by a gate signal supplied to the gate line GL and may supply a current output from the driving transistor Tdr to an adjacent reference voltage line RL, or may connect the source electrode SE of the driving transistor Tdr to an adjacent reference voltage line RL.

In each of a plurality of sub-pixel areas SPA1 to SPA4, the gate electrode GE of the second switching transistor Tsw2 may be a partial area of the gate line GL. The first source/drain electrode SDE1 of the second switching transistor Tsw2 may be electrically connected to the reference connection line RCL branched from the reference voltage line RL through a second contact hole CH2. The reference connection line RCL is disposed in parallel with the gate line GL and passes through the reference voltage line RL and may be electrically connected to the reference voltage line RL through a second contact hole CH2.

The storage capacitor Cst is formed between the gate electrode GE and the source electrode SE of the driving transistor Tdr. For example, the storage capacitor Cst may include a first capacitor electrode made of the gate electrode GE of the driving transistor Tdr, a second capacitor electrode made of the source electrode of the driving transistor Tdr, and a dielectric layer formed in an overlapping region between the first capacitor electrode and the second capacitor electrode. The storage capacitor Cst charges the voltage difference between the gate electrode GE and the source electrode SE of the driving transistor Tdr, and based on the charged voltage, it can switch the driving transistor Tdr.

The driving transistor Tdr may include a gate electrode GE connected to the second source/drain electrode SDE2 of the first switching transistor Tsw1, a source electrode SE connected to the first source/drain electrode SDE1 of the second switching transistor Tsw2, and a drain electrode DE connected to the pixel driving voltage line PL. The driving transistor Tdr is turned on by a voltage of the storage capacitor Cst, and thus, an amount of current flowing from the pixel driving voltage line PL to the light emitting device layer may be controlled.

Among the plurality of sub-pixel areas SPA1 to SPA4, the drain electrode DE of the driving transistor Tdr disposed in the first sub-pixel area SPA1 may be disposed in a protruding area protruding from the first pixel driving voltage line PL1. The drain electrode DE of the driving transistor Tdr disposed in the fourth sub-pixel area SPA4 may be disposed in a protruding area protruding from the second pixel driving voltage line PL2.

Among the plurality of sub-pixel areas SPA1 to SPA4, a drain electrode DE of the driving transistor Tdr disposed in the second sub-pixel area SPA2 may be electrically connected to the first pixel driving voltage line PL1 through a first internal power supply line IPL1. In this case, the first internal power supply line IPL1 may be disposed in parallel on the same layer as the gate line GL. The first internal power supply line IPL1 may be electrically connected to the first pixel driving voltage line PL1 through at least one third contact hole CH3 and may be electrically connected to the drain electrode DE of the driving transistor Tdr disposed in the second sub-pixel area SPA2 through the fourth contact hole CH4.

Among the plurality of sub-pixel areas SPA1 to SPA4, a drain electrode DE of the driving transistor Tdr disposed in the third sub-pixel area SPA3 may be electrically connected to the second pixel driving voltage line PL2 through a second internal power supply line IPL2. In this case, the second internal power supply line IPL2 may be disposed in parallel on the same layer as the gate line GL. The second internal power supply line IPL2 may be electrically connected to the second pixel driving voltage line PL2 through at least one fifth contact hole CH5 and may be electrically connected to the drain electrode DE of the driving transistor Tdr disposed in the third sub-pixel area SPA3 through the sixth contact hole CH6.

According to an embodiment of the present disclosure, each of the transistors Tsw1, Tsw2, and Tdr of the pixel circuit PC may be disposed on a buffer layer disposed on a substrate. The semiconductor layer may include a source region, a drain region, and a channel region. The channel region of the semiconductor layer may be covered by a gate insulating layer. Each of the gate line GL and the transistors Tsw1, Tsw2, and Tdr may be disposed on the gate insulating layer and may be covered by the interlayer insulating layer. The data line DL, the pixel driving voltage line PL, the reference voltage line RL, and source/drain electrode of the transistors Tsw1, Tsw2, and Tdr may be disposed on the interlayer insulating layer and may be covered by a passivation layer and a planarization layer (or a planarization layer).

In the first area A1, color filter layers CFr, CFb, and CFg may be formed between the passivation layer and the planarization layer. The color filter layers CFr, CFb, and CFg may be respectively configured in each of the first sub-pixel area SPA1, the third sub-pixel area SPA3, and the fourth sub-pixel area SPA4 among the plurality of sub-pixel areas SPA1 to SPA4. According to an embodiment of the present disclosure, in the second area A2, an auxiliary color filter layer CFLsub may be additionally configured in the same layer as the color filter layers CFr, CFb, and CFg. The auxiliary color filter layer CFLsub may absorb light reflection by a plurality of metal lines PL, DL, and RL. Accordingly, light reflection in the second area A2 may be further reduced.

A light emitting device layer connected to the transistor may be formed on the planarization layer, and an encapsulation layer may be additionally formed on the light emitting device layer. The configuration of a light emitting display apparatus according to embodiments of the present disclosure will be described in detail with reference to the following drawings.

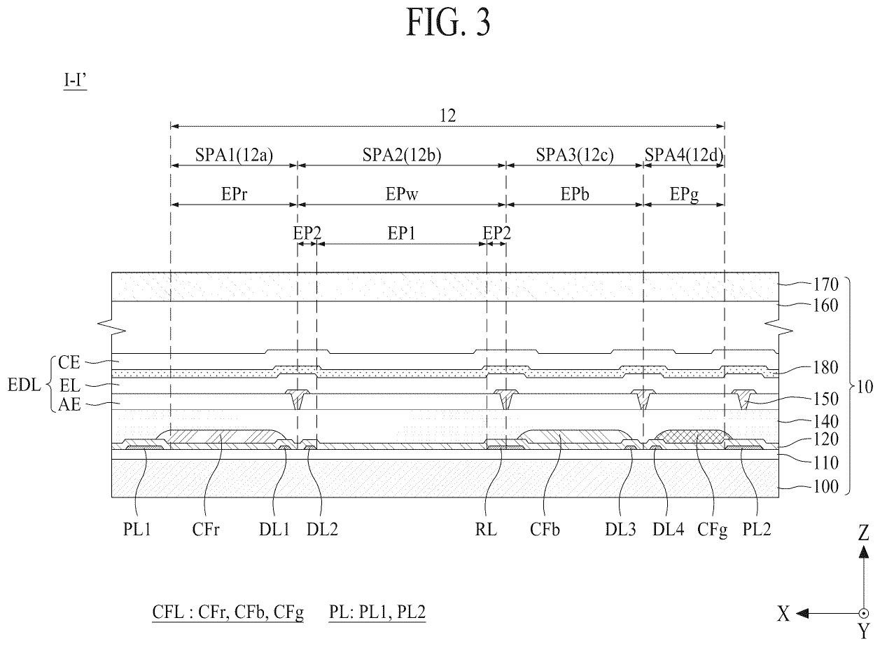

FIG. 3 is a cross-sectional view along the line I-I′ shown in FIG. 2 according to an embodiment of the present disclosure. This is a cross-sectional view of a light emitting area in a light emitting display apparatus according to an embodiment of the present disclosure described with reference to FIGS. 1 and 2. Therefore, hereinafter, substantially the same reference numerals are assigned to substantially the same configurations, and overlapping descriptions are briefly described or omitted.

Referring to FIGS. 2 and 3, a light emitting display apparatus according to an embodiment of the present disclosure may include a substrate 100, a buffer layer 110, a plurality of metal lines PL, DL and RL, a passivation layer 120, a color filter layer CFL, a planarization layer 140, a light emitting device layer EDL, and a light absorbing layer 180.

The substrate 100 includes a transistor and may be a transistor array substrate, a lower substrate, a base substrate, or a first substrate. The substrate 100 may be a transparent glass substrate or a transparent plastic substrate.

The substrate 100 may include a first light emitting area EP1 and a second light emitting area EP2. The first light emitting area EP1 may be disposed between the first metal line and the second metal line, and the second light emitting area EP2 may overlap at least one of the first metal line and the second metal line. For example, based on the first direction X, the second light emitting area EP2 may overlap at least half of at least one of the first metal line and the second metal line. For example, when the sub-pixel area is the second sub-pixel area SPA2, the first metal line may be the second data line DL2, and the second metal line may be the reference voltage line RL. For example, when the sub-pixel area is the fourth sub-pixel area SPA4, the first metal line may be the fourth data line DLA and the second metal line may be the second pixel driving voltage line PL2.

The buffer layer 110 may be configured on a surface (or the front surface) of the substrate 100. The buffer layer 110 may block the diffusion of substances contained in the substrate 100 into the transistor layer during the high-temperature process in the manufacturing of the thin-film transistor. For example, the buffer layer 110 may include an inorganic material such as silicon oxide (SiOx) or silicon nitride (SiNx).

The plurality of metal lines PL, DL, and RL may be configured on the buffer layer 110. The plurality of metal lines PL, DL, and RL may be configured in the second light emitting region EP2 of the substrate 100. The plurality of metal lines PL, DL, and RL may include first and second driving voltage lines PL1 and PL2, first to fourth data lines DL1, DL2, DL3, and DL4, and the reference voltage line RL. The plurality of metal lines PL, DL, and RL include the same material and may be formed by using the same process. For example, a plurality of metal lines PL, DL, and RL may include molybdenum (Mo), aluminum (Al), chromium (Cr), gold (Au), titanium (Ti), nickel (Ni), copper (Cu), tungsten (W), or an alloy thereof, and may be formed of a single layer of the metal or alloy or multiple layers of two or more layers such as Cu/MoTi. For example, the plurality of metal lines PL, DL, and RL may be composed of two or more layers including a low-reflective material such as tungsten oxide.

The passivation layer 120 may be configured on the buffer layer 110 while covering a plurality of metal lines PL, DL, and RL. The passivation layer 120 may cover the entire upper surface of the buffer layer 110. For example, the passivation layer 120 may include an inorganic material such as silicon oxide (SiOx) or silicon nitride (SiNx).

The color filter layer CFL may be disposed to overlap the light emitting portions EPr, EPb, and EPg of each of the first, third, and fourth sub-pixel areas SPA1, SPA3, and SPA4 among the plurality of sub-pixel areas SPA1 to SPA4. The color filter layer CFL may be configured between the substrate 100 and the planarization layer 140. For example, the color filter layer CFL may be interposed between the passivation layer 120 and the planarization layer 140.

The color filter layer CFL may include a red color filter CFr overlapping the red light emitting portion EPr of the first sub-pixel area SPA1, a blue color filter CFb overlapping the blue light emitting portion EPb of the third sub-pixel area SPA3, and a green color filter CFg overlapping the green light emitting portion EPg of the fourth sub-pixel area SPA4.

The red color filter CFr, blue color filter CFb, and green color filter CFg may each have a size larger than or wider than the corresponding light emitting portions EPr, EPb, and EPg. For example, each of the red color filter CFr, the blue color filter CFb, and the green color filter CFg may have a size larger or wider than the corresponding light emitting portions EPr, EPb, and EPg in order to prevent or minimize light leakage from other adjacent sub-pixel areas.

The ends of the red color filter CFr, blue color filter CFb, and green color filter CFg may each overlap with the first and second metal lines PL, DL, and RL that are adjacent to each other, with the corresponding light emitting portions EPr, EPb, and EPg in between. For example, the ends of each of the red color filter CFr, the blue color filter CFb, and the green color filter CFg may be located on the adjacent metal lines PL, DL, and RL.

According to an embodiment of the present disclosure, each of the red color filter CFr, the blue color filter CFb, and the green color filter CFg may include quantum dots, and the quantum dots re-emit light according to light emitted from the light emitting device layer EDL toward the substrate 100. The quantum dots of each color filter may have a size that emits light of a color set in the sub-pixel that corresponds to the color filter. In this case, the red color filter CFr may further include a long-wavelength absorbing material (or dye) that does not contain red quantum dots or absorbs at least a portion of long-wavelength light so that transmittance (or emission rate) of light in a long-wavelength region may be reduced. For example, the long-wavelength absorbing material may absorb wavelengths of 620 nm to 700 nm, and thus, transmittance (or emission rate) of light in a long-wavelength region may be reduced and a color temperature may increase.

A planarization layer 140 may be configured on a substrate 100. A planarization layer 140 may be configured on the passivation layer 120 and the color filter layer CFL. A planarization layer 140 may be configured on a plurality of metal lines PL, DL, and RL, and transistors. For example, the planarization layer 140 may be configured to planarize upper portions of a plurality of metal lines PL, DL, and RL, and color filter layer CFL, which are configured below. As another example, the planarization layer 140 may not be completely planarized by the color filter layer CFL, which is relatively thick compared to a plurality of metal lines PL, DL, RL, and transistors.

According to an embodiment of the present disclosure, a color filter layer may not be configured on the white light emitting portion EPw among a plurality of light emitting portions EPr, EPw, EPb, and EPg. That is, the white light emitting portion EPw lacks a color filter layer. Accordingly, the planarization layer 140 configured on the white light emitting portion EPw may have a step difference compared to the planarization layer 140 formed on the red, blue, and green light emitting portions EPr, EPb, and EPg. For example, in order to reduce a step difference in each of a plurality of light emitting portions EPr, EPw, EPb, and EPg, the thickness of the planarization layer 140 may be adjusted according to required specifications of the light emitting display apparatus.

The light emitting device layer EDL may be configured in the light emitting portion EP of each of the plurality of sub-pixel areas SPA1 to SPA4. The light emitting device layer EDL may include a first electrode AE, a light emitting layer EL, and a second electrode CE. The first electrode AE may be an anode electrode and the second electrode CE may be a cathode electrode, but is not limited thereto.

The first electrode AE may be individually disposed on the planarization layer 140 on the substrate 100 corresponding to the light emitting portion EP of each of the plurality of sub-pixel areas SPA1 to SPA4. Thus, each sub-pixel area SPA1 to SPA4 has its own corresponding first electrode AE. According to an embodiment, the first electrode AE of each sub-pixel area may have a size and a shape corresponding to the light emitting portion EP of each of the plurality of sub-pixel areas SPA1 to SPA4. The first electrode AE may be made of a transparent conductive material such as a transparent conductive oxide (TCO) so that light emitted from the light emitting layer EL may be transmitted to the outside.

According to an embodiment of the present disclosure, the first electrode AE may be in direct contact with an uppermost surface of the planarization layer 140. For example, the first electrode AE may be configured to have a shape following the morphology of the planarization layer 140. For example, the first electrode AE of each of a plurality of sub-pixel areas SPA1 to SPA4 may include an extension portion extending toward a corresponding pixel circuit. The extension portion of the first electrode AE may be electrically connected to a source or drain electrode of a driving transistor of a corresponding pixel circuit through an electrode contact hole disposed in the planarization layer 140 and the passivation layer 120. Accordingly, the first electrode AE of each of a plurality of sub-pixel areas SPA1 to SPA4 may individually receive the data current from the driving transistor of a corresponding pixel circuit.

According to an embodiment of the present disclosure, the light emitting display apparatus may further include a bank 150. The bank 150 covers one end and the other end of the first electrode AE and may partition each of a plurality of sub-pixel areas SPA1 to SPA4. The bank 150 may be provided between each of a plurality of sub-pixel areas SPA1 to SPA4. The bank 150 may be configured to cover the pixel circuit PC disposed in the second area A2 (or the circuit area). The bank 150 according to an embodiment may be a black bank including a black dye. For example, the bank 150 may include an organic material and/or an inorganic material. When the bank 150 is a black bank including a black dye, light in the first area A1 and the second area A2 (or the circuit area) may be absorbed to further reduce reflection by external light.

The light emitting layer EL of the light emitting device layer EDL may be configured on the entire surfaces of the first to fourth sub-pixel areas SPA1 to SPA4. Thus, the light emitting layer EL is common to the first to fourth sub-pixel areas SPA1 to SPA4. The light emitting layer EL may be configured on the first electrode AE and the bank 150 in each of the first to fourth sub-pixel areas SPA1 to SPA4. The light emitting layer EL may cover the first electrode AE and the bank 150 in each of the first to fourth sub-pixel areas SPA1 to SPA4.

The light emitting layer EL may be an organic light emitting device, a quantum dot light emitting device, an inorganic light emitting device, or a micro light emitting diode device. For example, the light emitting layer EL made of the organic light emitting device may include a hole functional layer disposed on the first electrode, an organic light emitting layer disposed on the hole functional layer, and an electronic functional layer disposed on the organic light emitting layer.

According to an embodiment of the present disclosure, the light emitting layers EL disposed in each of the first to fourth sub-pixel areas SPA1 to SPA4 may be disposed to emit light of different colors. Thus, each sub-pixel has its own corresponding light emitting layer EL. For example, the light emitting layer EL of the first sub-pixel area SPA1 may include a red organic light emitting layer. The light emitting layer EL of the third sub-pixel area SPA3 may include a blue organic light emitting layer. The light emitting layer EL of the fourth sub-pixel area SPA4 may include a green organic light emitting layer. In addition, the light emitting layer EL of the second sub-pixel area SPA2 may include a plurality of organic light emitting layers for emitting white light.

According to an embodiment of the present disclosure, the light emitting layer EL of the second sub-pixel area SPA2 may have a stack structure in which first and second organic light emitting layers are stacked. The first organic light emitting layer according to an embodiment emits the first light and may include any one of a blue organic light emitting cell, a green organic light emitting cell, a red organic light emitting cell, a yellow organic light emitting cell, and a yellow-green organic light emitting cell. The second organic light emitting layer according to an embodiment may include any one of a blue organic light emitting cell, a green organic light emitting cell, a red organic light emitting cell, a yellow organic light emitting cell, and a yellow-green organic light emitting cell except for the organic light emitting cell of the first organic light emitting layer. Additionally, the light emitting layer EL of the second sub-pixel area SPA2 may further include a third organic light emitting layer including any one of the blue organic light emitting cell, the green organic light emitting cell, the red organic light emitting cell, the yellow organic light emitting cell, and the yellow-green organic light emitting cell except for the first and second organic light emitting cells.

According to another example, the light emitting layers EL disposed in each of the first to fourth sub-pixel areas SPA1 to SPA4 may be disposed as a common layer emitting white light. For example, the light emitting layers EL disposed in each of the first to fourth sub-pixel areas SPA1 to SPA4 may include a first organic light emitting layer and the second organic light emitting layer, or may include the first organic light emitting layer, the second organic light emitting layer, and the third organic light emitting layer. In this case, the light emitting layer EL may be in direct contact with the first electrode AE disposed in each of the first to fourth sub-pixel areas SPA1 to SPA4.

Additionally, the emission layer EL disposed in each of the first to fourth sub-pixel areas SPA1 to SPA4 may be changed to a quantum dot light emitting device or may further include a quantum dot emission layer to improve color reproduction.

The second electrode CE of the light emitting device layer EDL may be disposed on the entire display area of the substrate 100 to be in direct contact with the light emitting layer EL. The second electrode CE according to an embodiment may include a metal material having high reflectivity in order to reflect light emitted and incident from the light emitting layer EL toward the substrate 100. For example, the second electrode CE may include aluminum (Al). For example, the thickness of the second electrode CE may be in a range of 1800 Å to 2000 Å.

According to an embodiment of the present disclosure, a light absorbing layer 180 is located between the light emitting layer EL and the second electrode CE. The light absorbing layer 180 may cover the entire upper surface of the light emitting layer EL across the sub-pixels SPA1 to SPA4. The light absorbing layer 180 may include the same material as the second electrode CE, but is a distinct layer from the second electrode CE. Thus, the lower surface of the second electrode CE is in direct contact with an upper surface of the light absorbing layer 180. For example, the light absorbing layer 180 may include aluminum (Al). The light absorbing layer 180 may have a thickness different from a thickness of the second electrode CE, and the light absorbing layer 180 may have a refractive index and a reflectance that is respectively different from a refractive index and a reflectance of the second electrode CE. For example, the light absorbing layer 180 may be a semitransparent layer or a semitransparent film.

The following Tables 1 and 2 show reflectance and efficiency of the light absorbing layer 180 according to the thin film thickness. In Table 1, reflectance represents reflectance of a white sub-pixel region. In Table 2, efficiency represents light emission efficiency of a white sub-pixel.

TABLE 1

| | The thin film thickness of | | | | |
|---|---|---|---|---|---|
| | the light absorbing layer (Å) | | | | |
| | 0 Å | 50 Å | 100 Å | 150 Å | 200 Å |
| Reflectance (%) | 74.5% | 63.3% | 48.9% | 35.7% | 26.4% |

Referring to Table 1, the light absorbing layer 180 showed lower reflectance as the thickness increased from 0 Å to 200 Å, and showed the lowest reflectance when the thickness was 200 Å.

TABLE 2

The thin film thickness of
the light absorbing layer (Å)

| | 0 Å | 50 Å | 100 Å | 150 Å | 200 Å |
|---|---|---|---|---|---|
| Efficiency | 68.08 | 69.06 | 65.48 | 59.64 | 53.94 |

Referring to Table 2, the light absorbing layer 180 showed the highest luminous efficiency at 50 Å, and the luminous efficiency tended to decrease as the thickness increased from 50 Å to 200 Å.

Referring to FIG. 3, Table 1, and Table 2, the refractive index and the reflectance of the light absorbing layer 180 may be adjusted by adjusting the deposition rate of the light absorbing layer 180. According to an embodiment, the deposition rate of the light absorbing layer 180 may be 1.7 Å/s to 1.8 Å/s. When the light absorbing layer 180 of 100 Å is configured at a deposition rate of 1.7 Å/s to 1.8 Å/s, the refractive index of the light absorbing layer 180 may have a value in the range of 3.4 to 3.5 in the wavelength range of 550 nm. In this case, the reflectance of the white sub-pixel may be 48.9% or less. When the light absorbing layer 180 of 50 Å is configured at a deposition rate of 1.7 Å/s to 1.8 Å/s, the reflectance of the white sub-pixel may be 63.3% of less. For example, in the final product, the light emitting display panel reflectance of the light emitting display apparatus may be 3.9% or less. In order to achieve the panel reflectance, the reflectance of the sub-pixel including the white sub-pixel may be reduced. For example, when the light absorbing layer 180 is not configured, the reflectance of the white sub-pixel may be about 75%. According to a configuration of the present disclosure, by configuring the light absorbing layer 180, the reflectance of the white sub-pixel may be reduced by 10% or more.

According to an embodiment of the present disclosure, a thickness range of the light absorbing layer 180 may be set in consideration of reflectance and efficiency. For example, the efficiency of the light emitting display apparatus should be maintained at least 65%, and thus, the thickness of the light absorbing layer 180 may be 100 Å or less in consideration of reflectance and efficiency. For example, the thickness of the light absorbing layer 180 may be 30 Å to 100 Å or less in consideration of reflectance and efficiency.

For example, the external light incident from the outside, as well as the light reflected by multiple metal lines PL, DL, and RL or transistors, may be reflected by the second electrode CE. The reflection of such external light may reduce the visibility of the light-emitting display apparatus. To prevent this, an additional optical film or the like may be attached to the substrate 100, but this may add to the process and cost.

According to an embodiment of the present disclosure, by configuring a light absorbing layer 180 with a refractive index different from that of the second electrode CE between the light-emitting layer EL and the second electrode CE, some of the external light incident on the second electrode CE can be absorbed. Accordingly, the reflection caused by external light in the light-emitting display apparatus according to the embodiment of present disclosure can be reduced, and the visibility of the light-emitting display apparatus can be improved.

Also, according to an embodiment of the present disclosure, by configuring the light absorbing layer 180, which is a semitransparent film containing the same material as the second electrode CE, between the light-emitting layer EL and the second electrode CE, an additional process for preventing reflection of external light may not be required after manufacturing the display panel. Accordingly, the manufacturing process of the light emitting display apparatus can be unified, and there is an effect of uni-materialization.

According to an embodiment of the present disclosure, the light emitting display apparatus may further include an encapsulation layer 160. The encapsulation layer 160 may be formed on the display area of the substrate 100 to cover the second electrode CE. The encapsulation layer 160 protects the thin-film transistor and light-emitting layer EL from external impacts, and can prevent oxygen and/or moisture, as well as foreign particles, from penetrating into the light-emitting device layer EDL. For example, the encapsulation layer 160 may include at least one inorganic layer. For example, the encapsulation layer 160 may further include at least one organic layer. For example, the encapsulation layer 160 may include a first inorganic encapsulation layer, an organic encapsulation layer on the first inorganic encapsulation layer, and a second inorganic encapsulation layer on the organic encapsulation layer, but is not limited thereto.

In one embodiment, the encapsulation layer 160 may be changed to a filler surrounding the entire pixel. In this case, the light emitting display apparatus according to an embodiment of the present disclosure may further include an encapsulation substrate 170 attached onto the substrate 100 via a filler. The encapsulation substrate 170 may be formed of a plastic material, a glass material, or a metal material. For example, the filler may include a getter material that absorbs oxygen or/and moisture, but is not limited thereto.

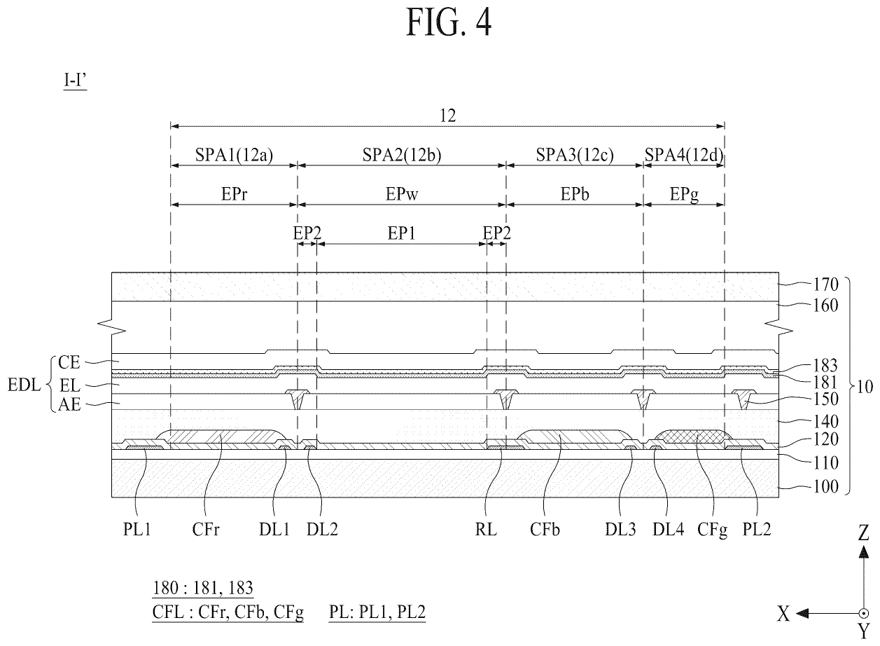

FIG. 4 is a cross-sectional view along line I-I′ shown in FIG. 2 according to another embodiment of the present disclosure. This is a change in the configuration of the light absorbing layer in the light emitting display apparatus illustrated in FIGS. 1 to 3. Accordingly, hereinafter, the light absorbing layer and the related configuration will be described, the remaining configurations will be given the same reference numerals as in FIGS. 1 to 3, and redundant descriptions thereof will be simply described or omitted.

Referring to FIG. 4, a light absorbing layer 180 according to another embodiment of the present disclosure may include a first light absorbing layer 181 and a second light absorbing layer 183 on the first light absorbing layer 181. The first light absorbing layer 181 may be configured on the light emitting layer EL such that the first light absorbing layer 181 is between the light emitting layer and the second light absorbing layer 183. The first light absorbing layer 181 may cover the entire upper surface of the light emitting layer EL. The second light absorbing layer 183 may be configured on the first light absorbing layer 181 such that the second light absorbing layer 183 is between the second electrode CE and the first light absorbing layer 181. The second light absorbing layer 183 may cover the entire upper surface of the first light absorbing layer 181.

According to another embodiment of the present disclosure, the first light absorbing layer 181 and the second light absorbing layer 183 may include the same material as the second electrode CE. For example, the first light absorbing layer 181 and the second light absorbing layer 183 may include aluminum (Al). Each of the first light absorbing layer 181 and the second light absorbing layer 183 may have a thickness that is different from the thickness of the second electrode CE. Each of the first light absorbing layer 181 and the second light absorbing layer 183 may have a refractive index and a reflectance that is respectively different from a refractive index and a reflectance of the second electrode CE.

Table 3 and Table 4 below show the reflectance and efficiency according to the thin film thickness of the first and second light absorbing layers 181 and 183, respectively. In Table 3, the reflectance represents the reflectance of the white sub-pixel area. In Table 4, the efficiency represents the light emission efficiency of the white sub-pixel.

TABLE 3

| | | The thin film thickness of the first | | | | |
|---|---|---|---|---|---|---|
| | | light absorbing layer (Å) | | | | |
| Reflectance | | 0 Å | 50 Å | 100 Å | 150 Å | 200 Å |
| The thin | 0 Å | 74.5% | 63.3% | 48.9% | 35.7% | 26.4% |
| film | 50 Å | 69.5% | 58.3% | 46.6% | 37.1% | 30.8% |
| thickness | 100 Å | 63.1% | 53.4% | 44.7% | 38.3% | 34.1% |
| of the | 150 Å | 56.8% | 49.3% | 43.3% | 39.1% | 36.5% |
| second | 200 Å | 51.6% | 46.2% | 42.3% | 39.6% | 38.1% |
| light | | | | | | |
| absorbing | | | | | | |
| layer(Å) | | | | | | |

Referring to Table 3, the first light absorbing layer 181 showed lower reflectance as the thickness increased from 0 Å to 200 Å and showed the lowest reflectance when the thickness was 200 Å. The second light absorbing layer 183 showed lower reflectance as the thickness increased from 0 Å to 200 Å and showed the lowest reflectance when the thickness was 200 Å.

TABLE 4

| | | The thin film thickness of the first | | | | |
|---|---|---|---|---|---|---|
| | | light absorbing layer (Å) | | | | |
| Efficiency | | 0 Å | 50 Å | 100 Å | 150 Å | 200 Å |
| The thin | 0 Å | 68.08 | 69.06 | 65.48 | 59.64 | 53.94 |
| film | 50 Å | 70.94 | 69.15 | 64.92 | 60.09 | 55.97 |
| thickness | 100 Å | 71.06 | 68.05 | 64.17 | 60.50 | 57.63 |
| of the | 150 Å | 69.66 | 66.57 | 63.46 | 60.83 | 58.91 |
| second | 200 Å | 67.78 | 65.17 | 62.87 | 61.08 | 59.85 |
| light | | | | | | |
| absorbing | | | | | | |
| layer(Å) | | | | | | |

Referring to Table 4, the first light absorbing layer 181 showed the highest light emission efficiency at 50 Å, and the light emission efficiency tended to decrease as the thickness increased from 50 Å to 200 Å. The second light absorbing layer 183 showed the high light emission efficiency at 50 Å and 100 Å, and the light emission efficiency tended to decrease as the thickness increased from 150 Å to 200 Å.

The thicknesses of the first light absorbing layer 181 and the second light absorbing layer 183 according to the embodiment of the present disclosure may be set in consideration of semi-transmissivity, reflectance, and efficiency. For example, the efficiency of the light emitting display apparatus should be maintained at 65% or more, and thus, the thickness of the first light absorbing layer 181 according to the embodiment of the present disclosure may be set to a thickness of 100 Å or less in consideration of semi-transmissivity, reflectance, and efficiency. For example, when the thickness of the second light absorbing layer 183 is 150 Å or more in consideration of semi-transmissivity, reflectance, and efficiency, the efficiency can be lowered. Therefore, the thickness can be set to 100 Å or less. For example, the thickness of the first light absorbing layer 181 may be 30 Å to 100 Å or less in consideration of reflectivity and efficiency, and the thickness of the second light absorbing layer 183 may be 30 Å to 100 Å or less in consideration of reflectivity and efficiency. However, the thickness is not necessarily limited thereto, and the thickness of the light absorbing layer 180 may be set according to specifications required for a light emitting display apparatus.

According to another embodiment of the present disclosure, the first light absorbing layer 181 and the second light absorbing layer 183 may have the same thickness, but are not limited thereto. For example, the thickness of each of the first light absorbing layer 181 and the second light absorbing layer 183 may be 100 Å or less. For example, the thickness of each of the first light absorbing layer 181 and the second light absorbing layer 183 may be 50 Å. Accordingly, each of the first light absorbing layer 181 and the second light absorbing layer 183 may be a semi-transmissive layer or a semi-transmissive film. Thus, each of the first light absorbing layer 181 and the second light absorbing layer 183 is semi-transmissive.

The first light absorbing layer 181 and the second light absorbing layer 183 may be deposited at different deposition rates. For example, the deposition rate of the first light absorbing layer 181 may be 1.7 Å/s to 1.8 Å/s. For example, the deposition rate of the second light absorbing layer 183 may be 3.4 Å/s to 3.6 Å/s. Accordingly, the first light absorbing layer 181 and the second light absorbing layer 183 may have different refractive indices. For example, each of the first light absorbing layer 181 and the second light absorbing layer 183 may include the same aluminum material. According to an embodiment of the present disclosure, the first light absorbing layer 181 and the second light absorbing layer 183 having different refractive indices may be realized by differently controlling the deposition rate of the aluminum material. For example, when each of the first light absorbing layer 181 and the second light absorbing layer 183 has a thickness of 50 Å, the refractive index of the first light absorbing layer 181 may be 3.4 to 3.5 at a wavelength of 550 nm. When each of the first light absorbing layer 181 and the second light absorbing layer 183 has a thickness of 50 Å, the refractive index of the second light absorbing layer 183 may be 2.4 to 2.6 at a wavelength of 550 nm. Reflectivity of the light absorbing layer 180 including two layers according to another embodiment of the present disclosure may be 58.3% or less.

For example, in the final product, the reflectance of the light emitting display panel of the light emitting display apparatus may be 3.9% or less. To implement this, the reflectance of the sub-pixel including the white sub-pixel may be reduced. For example, when the light absorbing layer 180 is not configured, the reflectance of the white sub-pixel may be about 75%. According to the embodiment of the present disclosure, by configuring the light absorbing layer 180, the reflectance of the white sub-pixel may be reduced by 10% or more.

A light emitting display apparatus according to another embodiment of the present disclosure may have the same effect as the light emitting display apparatus according to an embodiment of the present disclosure described with reference to FIG. 3.

According to another embodiment of the present disclosure, the light emitting display apparatus includes a light absorbing layer 180 composed of two layers having different refractive indices, and thus, reflection by external light may be further reduced, and visibility of the light emitting display apparatus may be further improved.

According to another embodiment of the present disclosure, the light emitting display apparatus includes a light absorbing layer 180 made of the same material and composed of two layers having different refractive indices, and thus, after manufacturing the display panel, an additional process of attaching a film or the like for preventing reflection of external light may not be required. Accordingly, the process of the light emitting display apparatus may be simplified and the manufacturing cost may be reduced.

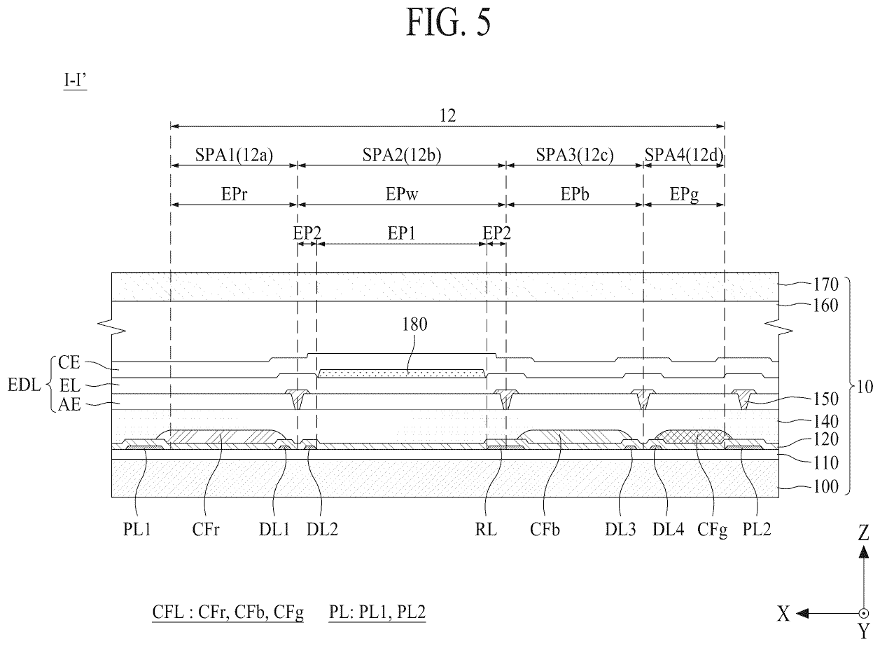

FIG. 5 is a cross-sectional view along line I-I′ shown in FIG. 2 according to another embodiment of the present disclosure. This is a change in the configuration of the light absorbing layer in the light emitting display apparatus illustrated in FIGS. 1 to 3. Accordingly, hereinafter, the light absorbing layer and the related configuration will be described, the remaining configurations will be given the same reference numerals as in FIGS. 1 to 3, and redundant descriptions thereof will be simply described or omitted.

Referring to FIG. 5, a light absorbing layer 180 according to another embodiment of the present disclosure may be provided between the light emitting layer EL and the second electrode CE. The light absorbing layer 180 may include the same material as the second electrode CE. For example, the light absorbing layer 180 may include aluminum (Al). The light absorbing layer 180 may have a thickness, a refractive index, and a reflectance different from those of the second electrode CE. For example, the light absorbing layer 180 may be a semi-transmissive layer or a transmissive film. Thus, the light absorbing layer 180 is semi-transmissive.

According to another embodiment of the present disclosure, as shown in FIG. 3, the thickness range of the light absorbing layer 180 may be set in consideration of reflectance and efficiency of the light absorbing layer 180. For example, the efficiency of the light emitting display apparatus should be maintained at 65% or more, and thus, the thickness of the light absorbing layer 180 may be 100 Å or less in consideration of reflectance and efficiency. For example, the thickness of the light absorbing layer 180 may be 30 Å to 100 Å or less in consideration of reflectance and efficiency.

According to another embodiment of the present disclosure, the light absorbing layer 180 may be configured to correspond to the second sub-pixel area SPA2 among a plurality of sub-pixel areas SPA1 to SPA4. The light absorbing layer 180 may be configured to correspond to the second sub-pixel 12b among a plurality of sub-pixels 12a, 12b, 12c, and 12d. Thus, the light absorbing layer 180 is disposed in the second sub-pixel 12b but not the first sub-pixel 12a, the third sub-pixel 12c, and the fourth sub-pixel 12d. The light absorbing layer 180 may be patterned to correspond to the second sub-pixel 12b among a plurality of sub-pixels 12a, 12b, 12c, and 12d. The second sub-pixel 12b among a plurality of sub-pixels 12a, 12b, 12c, and 12d may be a white sub-pixel. The light absorbing layer 180 may overlap the white sub-pixel without overlapping the red, blue, and green sub-pixels.

According to an embodiment of the present disclosure, the color filter layers CFr, CFb, and CFg may not be configured in the second sub-pixel area SPA2 among the plurality of sub-pixel areas SPA1 to SPA4. The second sub-pixel area SPA2 may be a second sub-pixel 12b. The second sub-pixel area SPA2 may be a white sub-pixel. The white sub-pixel does not include the color filter layers CFr, CFb, and CFg, and thus, absorption of external light reflected by the second electrode CE may be relatively small compared to other sub-pixels.

External light reflected by the second electrode CE may be partially absorbed while passing through the color filter layers CFr, CFb, and CFg configured in the first, third, and fourth sub-pixel areas SPA1, SPA3, and SPA4. For example, the color filter layers CFr, CFb, and CFg are not configured in the second sub-pixel area SPA2, and thus, the absorption rate of external light may be lower than that of other sub-pixels. For example, the color filter layers CFr, CFb, and CFg are not configured in the second sub-pixel area SPA2, and thus, the reflectance of external light may be higher than that of other sub-pixels.

According to another embodiment of the present disclosure, the light absorbing layer 180 is configured between the light emitting layer EL and the second electrode CE, has a different refractive index from the second electrode CE, and is configured to correspond to the white sub-pixel. Accordingly, reflectance by external light in the white sub-pixel may be reduced, and visibility of the light emitting display apparatus may be improved.

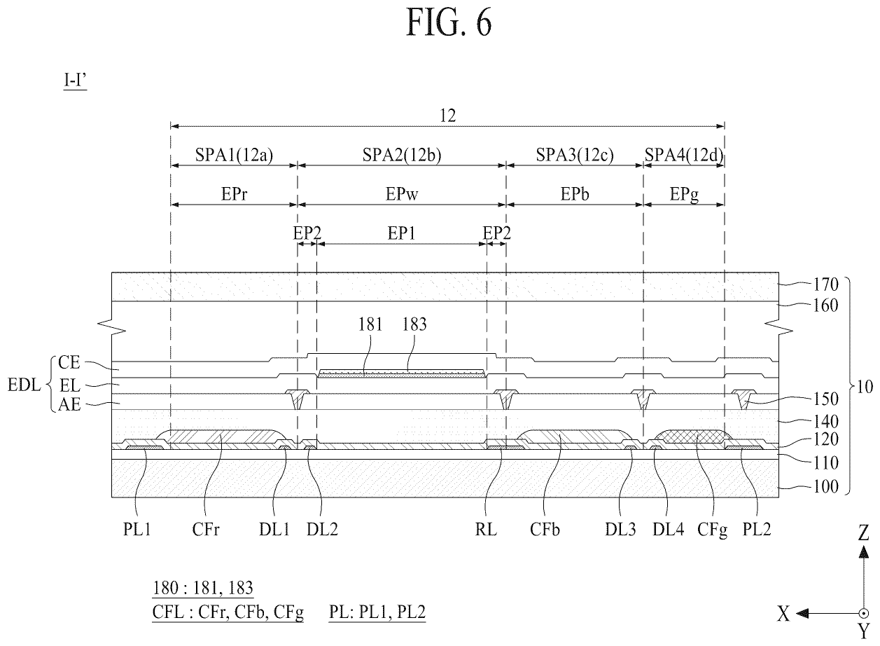

FIG. 6 is a cross-sectional view according to another example of the line I-I′ shown in FIG. 2. This is a change in the configuration of the light absorbing layer in the light emitting display apparatus shown in FIG. 4. Accordingly, hereinafter, the light absorbing layer and the related configuration will be described, the remaining configurations will be given the same reference numerals as in FIG. 4, and redundant descriptions thereof will be simply described or omitted.

Referring to FIG. 6, a light absorbing layer 180 according to another embodiment of the present disclosure may include a first light absorbing layer 181 and a second light absorbing layer 183. The first light absorbing layer 181 may be configured on the light emitting layer EL such that the first light absorbing layer 181 is between the light emitting layer EL and the second light absorbing layer 183. The second light absorbing layer 183 may be configured on the first light absorbing layer 181 such that the second light absorbing layer 183 is between the first light absorbing layer 181 and the second electrode CE. The first light absorbing layer 181 and the second light absorbing layer 183 may include the same material as the second electrode CE. For example, the first light absorbing layer 181 and the second light absorbing layer 183 may include aluminum (Al). Each of the first light absorbing layer 181 and the second light absorbing layer 183 may have a thickness different from the thickness of the second electrode CE. Each of the first light absorbing layer 181 and the second light absorbing layer 183 may have a refractive index and a reflectance that is respectively different from a refractive index and a reflectance of the second electrode CE. For example, as shown in FIG. 4, the thickness of the first light absorbing layer 181 may be 30 Å to 100 Å in consideration of reflectance and efficiency, and the thickness of the second light absorbing layer 183 may be 30 Å to 100 Å in consideration of reflectance and efficiency. However, it is not necessarily limited to this, and the thickness of the light absorbing layer 180 can be set according to the specifications required for the light emitting display apparatus.

According to another embodiment of the present disclosure, the first light absorbing layer 181 and the second light absorbing layer 183 may be configured to correspond to the second sub-pixel 12b among the plurality of sub-pixels 12a, 12b, 12c, and 12d. Thus, the first light absorbing layer 181 and the second light absorbing layer 183 are not disposed in the sub-pixels 12a, 12c, and 12d. The second sub-pixel 12b among the plurality of sub-pixels 12a, 12b, 12c, and 12d may be a white sub-pixel. The first light absorbing layer 181 and the second light absorbing layer 183 may overlap the white sub-pixel without overlapping the red, blue, and green sub-pixels.

According to an embodiment of the present disclosure, the color filter layers CFr, CFb, and CFg may not be configured in the second sub-pixel area SPA2 among the plurality of sub-pixel areas SPA1 to SPA4. The second sub-pixel area SPA2 may be a second sub-pixel 12b. The second sub-pixel area SPA2 may be a white sub-pixel. The white sub-pixel does not include the color filter layers CFr, CFb, and CFg, and thus, absorption of external light reflected by the second electrode CE may be relatively small compared to other sub-pixels. For example, the white sub-pixel does not include the color filter layers CFr, CFb, and CFg, and thus, reflectance of external light may be higher than that of other sub-pixels.

According to another embodiment of the present disclosure, the light emitting display apparatus includes a light absorbing layer 180 composed of two layers having different refractive indices, and the light absorbing layer 180 may be configured to correspond to this white sub-pixel. Accordingly, reflection by external light in the white sub-pixel can be reduced, and visibility of the light emitting display apparatus can be improved.

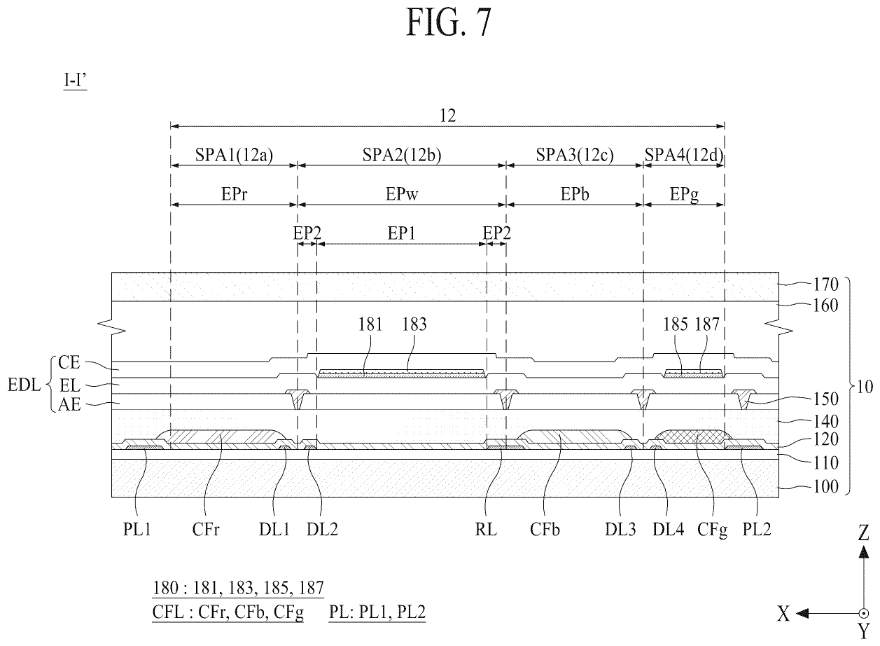

FIG. 7 is a cross-sectional view along line I-I′ shown in FIG. 2 according to another embodiment of the present disclosure. This is a change in the configuration of the light absorbing layer in the light emitting display apparatus illustrated in FIG. 6. Accordingly, hereinafter, the light absorbing layer and the related configuration will be described, the remaining configurations will be given the same reference numerals as in FIG. 6, and redundant descriptions thereof will be simply described or omitted.

Referring to FIG. 7, a light absorbing layer 180 according to another embodiment of the present disclosure may include first to fourth light absorbing layers 181, 183, 185, and 187. The configurations of the first light absorbing layer 181 and the second light absorbing layer 183 are the same as those of FIG. 6, and since they have the same effect, redundant descriptions are omitted.

The third light absorbing layer 185 and the fourth light absorbing layer 187 may be configured to correspond to (e.g., overlap) any one of the sub-pixel areas SPA1, SPA3, and SPA4 except for the second sub-pixel area SPA2 among a plurality of sub-pixel areas SPA1 to SPA4. Thus, the third and fourth light absorbing layers 185 and 187 are non-overlapping with the second sub-pixel area SPA2. The third light absorbing layer 185 and the fourth light absorbing layer 187 may correspond to any one of the first sub-pixel area SPA1, the third sub-pixel area SPA3, and the fourth sub-pixel area SPA4, but is shown in the fourth sub-pixel area SPA4 in FIG. 7.

The third light absorbing layer 185 and the fourth light absorbing layer 187 may be configured to correspond to the remaining sub-pixels 12a, 12c, and 12d except for the second sub-pixel 12b among the plurality of sub-pixels 12a, 12b, 12c, and 12d. The third light absorbing layer 185 and the fourth light absorbing layer 187 may be configured to correspond to any one of the first sub-pixel 12a, the third sub-pixel 12c, and the fourth sub-pixel 12d. The third light absorbing layer 185 may be patterned to correspond to any one of the first sub-pixel 12a, the third sub-pixel 12c, and the fourth sub-pixel 12d. Each of the first sub-pixel 12a, the third sub-pixel 12c, and the fourth sub-pixel 12d may be a red sub-pixel, a blue sub-pixel, and a green sub-pixel.

The fourth light absorbing layer 187 may be configured and patterned on the third light absorbing layer 185. According to an embodiment, the third light absorbing layer 185 and the fourth light absorbing layer 187 may overlap the green sub-pixel without overlapping the red and blue sub-pixels. According to another embodiment, the third light absorbing layer 185 and the fourth light absorbing layer 187 may overlap the red sub-pixel without overlapping the green and blue sub-pixels. According to another embodiment, the third light absorbing layer 185 and the fourth light absorbing layer 187 may overlap the blue sub-pixel without overlapping the red and green sub-pixels.

According to another embodiment of the present disclosure, the third light absorbing layer 185 and the fourth light absorbing layer 187 may include the same material as that of the second electrode CE. For example, the third light absorbing layer 185 and the fourth light absorbing layer 187 may include aluminum (Al). Each of the third light absorbing layer 185 and the fourth light absorbing layer 187 may have a thickness different from the thickness of the second electrode CE. Each of the third light absorbing layer 185 and the fourth light absorbing layer 187 may have a refractive index and a reflectance that is respectively different from a refractive index and a reflectance of the second electrode CE.

According to another embodiment of the present disclosure, the third light absorbing layer 185 and the fourth light absorbing layer 187 may have the same thickness, but are not limited thereto. For example, the thickness of each of the third light absorbing layer 185 and the fourth light absorbing layer 187 may be 50 Å or less. Accordingly, each of the third light absorbing layer 185 and the fourth light absorbing layer 187 may be a semi-transmissive layer or a semi-transmissive film. The third light absorbing layer 185 and the fourth light absorbing layer 187 may be deposited at different deposition rates. For example, the deposition rate of the third light absorbing layer 185 may be 1.7 Å/s to 1.8 Å/s. For example, the deposition rate of the fourth light absorbing layer 187 may be 3.4 Å/s to 3.6 Å/s. Accordingly, a refractive index of the third light absorbing layer 185 is different from a refractive index of the fourth light absorbing layer 187. For example, each of the third light absorbing layer 185 and the fourth light absorbing layer 187 may include the same aluminum material. According to an embodiment of the present disclosure, the third light absorbing layer 185 and the fourth light absorbing layer 187 having different refractive indices may be implemented by differently adjusting the deposition rate of the aluminum material.

According to another embodiment of the present disclosure, the third light absorbing layer 185 may have the same refractive index and reflectance as those of the first light absorbing layer 181. For example, the fourth light absorbing layer 187 may have the refractive index and reflectance as those of the second light absorbing layer 183. However, the present disclosure is not limited thereto, and the thickness, the refractive index, and the reflectance of each of the third light absorbing layer 185 and the fourth light absorbing layer 187 may be differently set according to an arranged pixel area.

A light emitting display apparatus according to another embodiment of the present disclosure may have the same effect as the light emitting display apparatus according to an embodiment of the present disclosure described with reference to FIG. 6.

According to another embodiment of the present disclosure, the light emitting display apparatus includes a third light absorbing layer 185 and a fourth light absorbing layer 187 having different refractive indices, and the third light absorbing layer 185 and the fourth light absorbing layer 187 are configured to correspond to the remaining sub-pixels 12a, 12c, and 12d except for the second sub-pixel 12b among the plurality of sub-pixels 12a, 12b, 12c, and 12d. Accordingly, reflection of external light may be selectively reduced in the remaining light emitting area except for the white light emitting area.

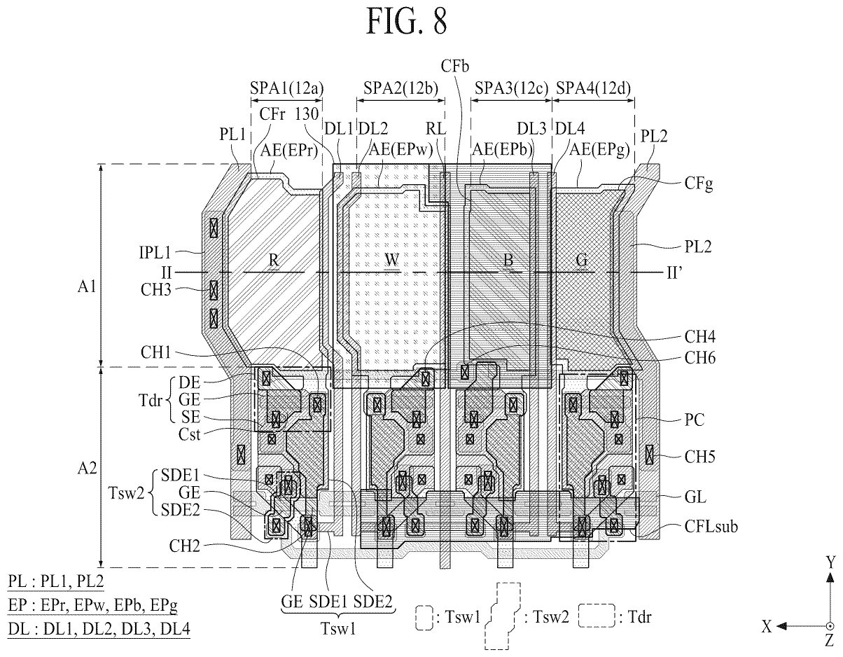

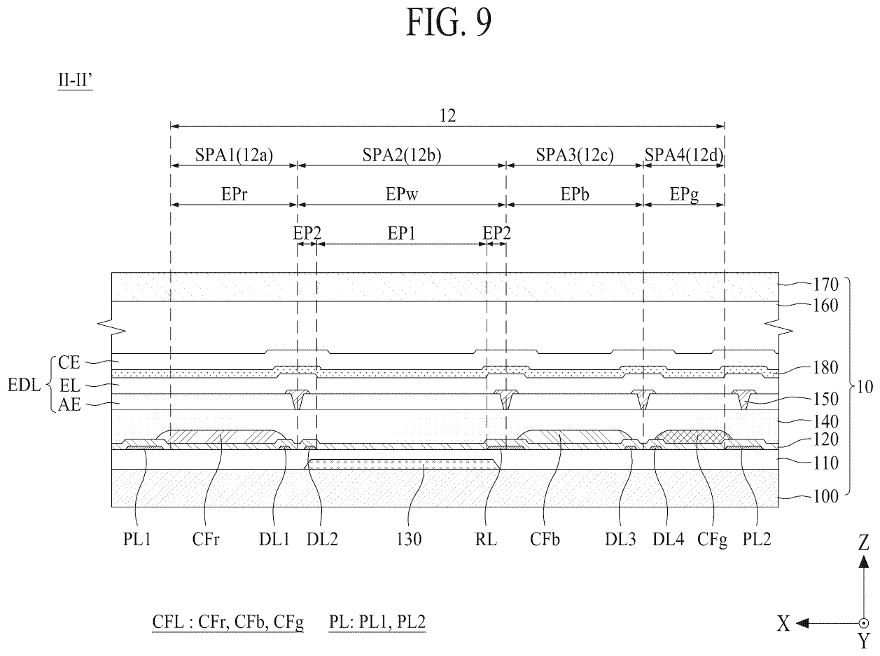

FIG. 8 is a diagram illustrating an arrangement structure of pixels illustrated in FIG. 1 according to another embodiment of the present disclosure. FIG. 9 is a cross-sectional view along line II-II′ shown in FIG. 8 according to one embodiment. There is a color control layer additionally configured in the light emitting display apparatus shown in FIGS. 1 to 3. Accordingly, hereinafter, the color control layer and the related configuration will be described, the remaining configurations will be given the same reference numerals as in FIGS. 1 to 3, and redundant descriptions thereof will be simply described or omitted.

Referring to FIGS. 8 and 9, a light emitting display apparatus according to another embodiment of the present disclosure may further include a color control layer 130. The color control layer 130 may be provided between the substrate 100 and the buffer layer 110. The color control layer 130 may overlap the light absorbing layer 180.

According to another embodiment of the present disclosure, the color control layer 130 may be configured to correspond to the second sub-pixel area SPA2 among a plurality of sub-pixel areas SPA1 to SPA4. The color control layer 130 may be configured to correspond to the second sub-pixel 12b among a plurality of sub-pixels 12a, 12b, 12c, and 12d. Thus, the color control layer is disposed in the second sub-pixel area SPA2/second sub-pixel 12b. The color control layer 130 may be patterned to correspond to the second sub-pixel 12b among a plurality of sub-pixels 12a, 12b, 12c, and 12d. Thus, the color control layer 130 is disposed in the second sub-pixel area SPA2 without being disposed in the first, third, and fourth sub-pixel areas SPA1, SPA3, and SPA4. The second sub-pixel 12b among a plurality of sub-pixels 12a, 12b, 12c, and 12d may be a white sub-pixel. The color control layer 130 may overlap the white sub-pixel without overlapping the red, green, and blue sub-pixels.

The color control layer 130 may include indium gallium zinc oxide InGaZnO₄(IGZO). The color control layer 130 may arbitrarily adjust the electron concentration in the layer through a hydrogen plasma treatment process and adjust the refractive index in the entire region of visible light. The extinction coefficient of the color control layer 130 in the visible light region approaches 0, and thus, light loss is extremely small and thus a thin film of a transmission form capable of transmitting very clear colors may be configured. For example, the color control layer 130 may have a refractive index different from that of the substrate 100 at 550 nm. According to another embodiment of the present disclosure, the color control layer 130 is configured of InGaZnO₄ (IGZO) having a refractive index different from that of the substrate 100, and thus, the reflection spectrum may be adjusted in the range of (3.51, −6.86) to (3.90, −7.36) of the color coordinates. The reflectance spectrum refers to the spectrum of light that is incident into the interior of a light-emitting apparatus, then reflected by the second electrode CE, and finally emitted outward.

The area of the color control layer 130 may be 100% or less of the area of the white sub-pixel. According to an embodiment of the present disclosure, the color control layer 130 may be configured to correspond to the entire surface of the white sub-pixel. For example, the color control layer 130 may have the same size as the white sub-pixel. Another example, the color control layer 130 may be configured in a line shape or an island shape in the first direction X at the center of the white sub-pixel. Another example, the color control layer 130 may be configured in a line shape or an island shape in the second direction Y at the center of the white sub-pixel. For example, the area or size of the color control layer 130 may be set according to the sizes of the low reflective layer and the auxiliary pattern portion to be described below.

According to another embodiment of the present disclosure, the light absorbing layer 180 having a refractive index different from that of the second electrode CE is configured between the light emitting layer EL and the second electrode CE, and thus, reflection by external light in the white sub-pixel may be reduced, and visibility of the light emitting display apparatus may be improved.

According to another embodiment of the present disclosure, the color control layer 130 is configured between the substrate 100 and the buffer layer 110, the reflection spectrum of the white sub-pixel in which the color filter layers CFr, CFb, and CFg are not formed may be controlled. For example, by forming the color control layer 130 between the substrate 100 and the buffer layer 110, the reflectance spectrum of light, which is reflected by the second electrode CE and emitted back outward in the white sub-pixel, can be controlled.

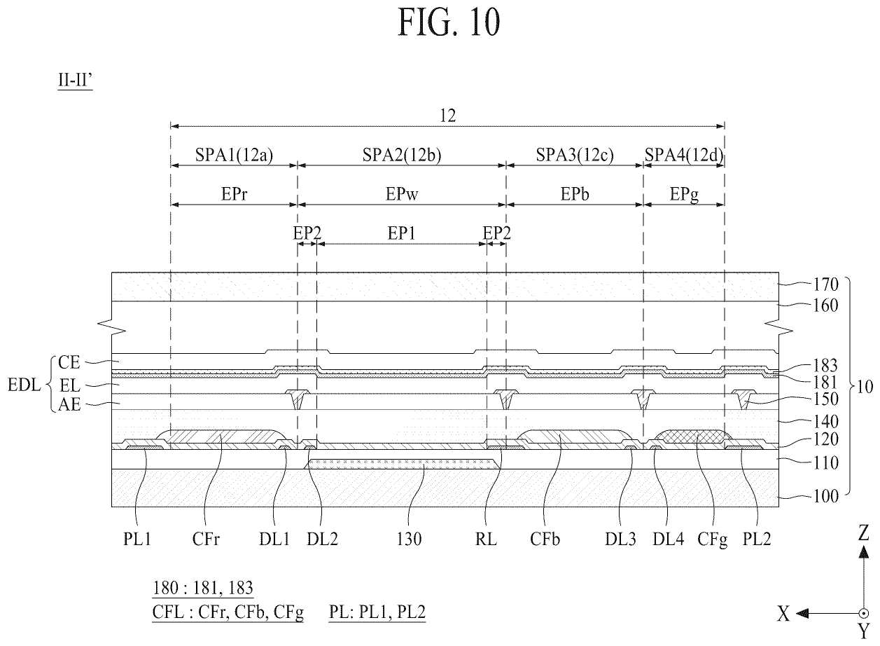

FIG. 10 is a cross-sectional view along line II-II′ shown in FIG. 8 according to another embodiment of the present disclosure. This is a color control layer additionally configured in the light emitting display apparatus shown in FIG. 4, and a configuration of the color control layer is the same as the configuration of the color control layer described in FIGS. 8 and 9. Accordingly, hereinafter, the color control layer and the related configuration will be described, the remaining configurations will be given the same reference numerals as in FIGS. 4, 8, and 9, and redundant descriptions thereof will be simply described or omitted.

Referring to FIG. 10, a light emitting display apparatus according to another embodiment of the present disclosure may include a first light absorbing layer 181, a second light absorbing layer 183, and a color control layer 130.

According to another embodiment of the present disclosure, the first light absorbing layer 181 and the second light absorbing layer 183 may be configured on an entire surface of the substrate. The first light absorbing layer 181 and the second light absorbing layer 183 may be stacked on each other. A configuration and an effect of the first light absorbing layer 181 and the second light absorbing layer 183 may be the same as those of the light emitting display apparatus described with reference to FIG. 4.

The color control layer 130 may be configured between the substrate 100 and the buffer layer 110. The color control layer 130 may overlap the first light absorbing layer 181 and the second light absorbing layer 183. The configuration and effect of the color control layer 130 may be the same as those of the light emitting display apparatus described with reference to FIGS. 8 and 9.

According to another embodiment of the present disclosure, the light absorbing layer 180 having a refractive index different from that of the second electrode CE is configured between the light emitting layer EL and the second electrode CE, and thus, reflection by external light in the white sub-pixel may be reduced, and visibility of the light emitting display apparatus may be improved.

According to another embodiment of the present disclosure, the color control layer 130 is configured between the substrate 100 and the buffer layer 110, the reflection spectrum of the white sub-pixel in which the color filter layers CFr, CFb, and CFg are not formed may be controlled. For example, by forming the color control layer 130 between the substrate 100 and the buffer layer 110, the reflectance spectrum of light, which is reflected by the second electrode CE and emitted back outward in the white sub-pixel, can be controlled.

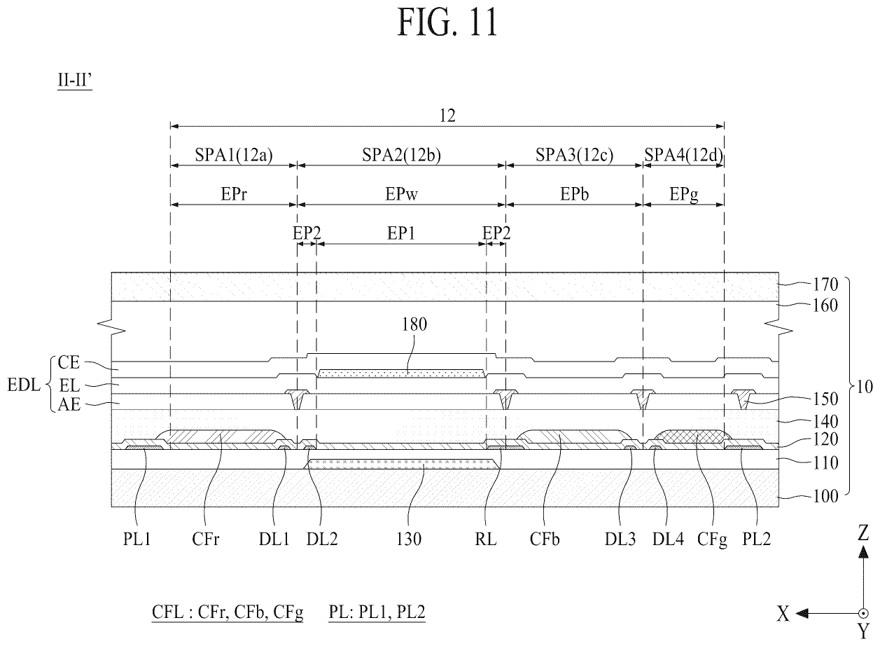

FIG. 11 is a cross-sectional view along line II-II′ shown in FIG. 8 according to another embodiment. This is a color control layer additionally configured in the light emitting display apparatus shown in FIG. 5, and a configuration of the color control layer is the same as the configuration of the color control layer described in FIGS. 8 and 9. Accordingly, hereinafter, the color control layer and the related configuration will be described, the remaining configurations will be given the same reference numerals as in FIGS. 5, 8, and 9, and redundant descriptions thereof will be simply described or omitted.

Referring to FIG. 11, a light emitting display apparatus according to another embodiment of the present disclosure may further include a light absorbing layer 180 and a color control layer 130. The light absorbing layer 180 may include first and second light absorbing layers 181 and 183 patterned in the white sub-pixel region but not the red, blue, and green sub-pixel regions. The color control layer 130 may be configured between the substrate 100 and the buffer layer 110. The color control layer 130 may overlap the first and second light absorbing layers 181 and 183. A configuration and an effect of the color control layer 130 may be the same as those of the light emitting display apparatus described with reference to FIGS. 8 and 9.

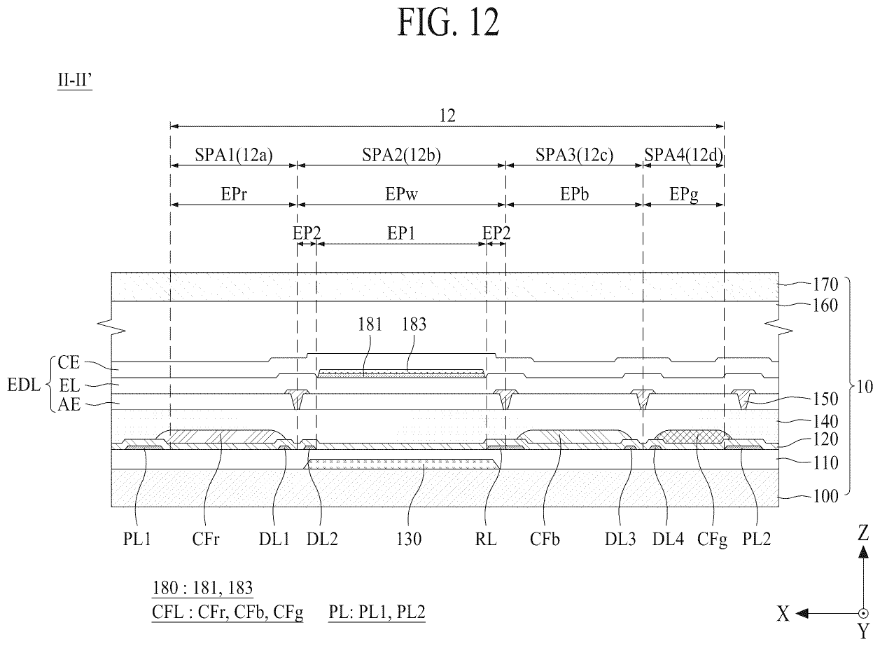

FIG. 12 is a cross-sectional view along line II-II′ shown in FIG. 8 according to another embodiment. This is a color control layer additionally configured in the light emitting display apparatus shown in FIG. 6, and a configuration of the color control layer is the same as the configuration of the color control layer described in FIG. 10. Accordingly, hereinafter, the color control layer and the related configuration will be described, the remaining configurations will be given the same reference numerals as in FIGS. 6 and 10, and redundant descriptions thereof will be simply described or omitted.

Referring to FIG. 12, a light emitting display apparatus according to another embodiment of the present disclosure may include a light absorbing layer 180 and a color control layer 130. The light absorbing layer 180 may include first and second light absorbing layers 181 and 183 patterned in the white sub-pixel region but not the red, blue, and green sub-pixel regions. The color control layer 130 may be configured between the substrate 100 and the buffer layer 110. The color control layer 130 may overlap the first and second light absorbing layers 181 and 183. A configuration and an effect of the color control layer 130 may be the same as those of the light emitting display apparatus described with reference to FIGS. 8 and 9.

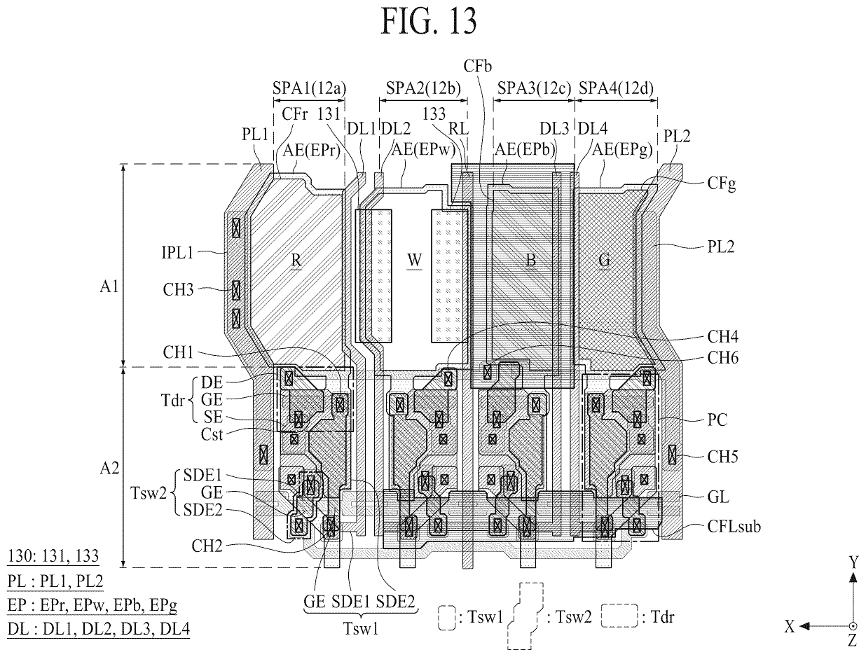

FIG. 13 is a diagram illustrating an arrangement structure of pixels illustrated in FIG. 1 according to another embodiment of the present disclosure. This is a change in the configuration of the color control layer in FIG. 8. Accordingly, hereinafter, the color control layer and the related configuration will be described, the remaining configurations will be given the same reference numerals as in FIG. 8, and redundant descriptions thereof will be simply described or omitted.

Referring to FIG. 13, a color control layer 130 according to another embodiment of the present disclosure may be disposed in parallel in the second direction Y. For example, the color control layer 130 may include a first color control layer 131 and a second color control layer 133. The first and second color control layers 131 and 133 may be disposed in parallel in the second direction Y. The first and second color control layers 131 and 133 may be spaced apart from each other.

Another embodiment of the present disclosure may have the same effect as the embodiment described with reference to FIG. 8. In addition, the light emitting display apparatus according to another embodiment of the present disclosure may be patternable according to the required specifications in the light emitting area. When the size or area of the color control layer 180 is adjusted, there is an effect of variously adjusting the reflective color according to the required specifications.

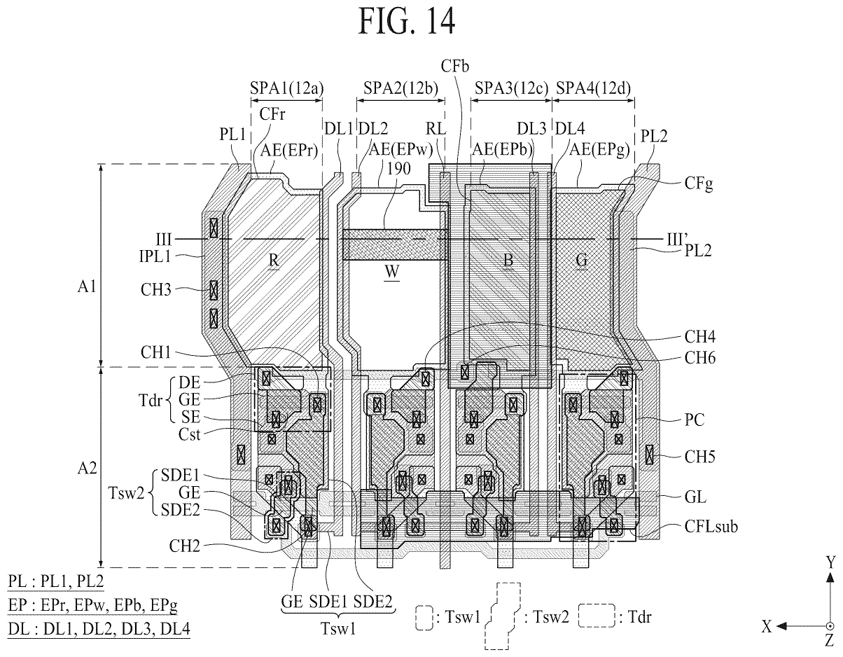

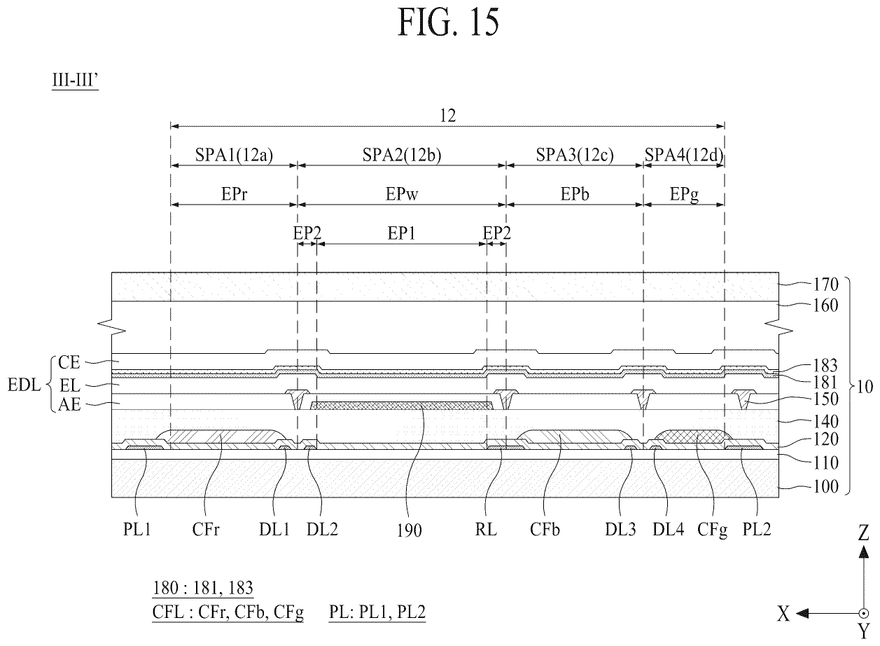

FIG. 14 is a diagram illustrating an arrangement structure of pixels illustrated in FIG. 1 according to another embodiment of the present disclosure. FIG. 15 is a cross-sectional view according to an example of the line III-III′ shown in FIG. 14 according to one embodiment. This is where a low reflective layer is additionally configured in the light emitting apparatus shown in FIG. 4. Accordingly, hereinafter, the low reflective layer and the related configuration will be described, the remaining configurations will be given the same reference numerals as in FIG. 4, and redundant descriptions thereof will be simply described or omitted.

Referring to FIGS. 14 and 15, the light emitting display apparatus according to another embodiment of the present disclosure may further include a low reflective layer 190. The low reflective layer 190 may be configured to correspond to the second sub-pixel area SPA2 among a plurality of sub-pixel areas SPA1 to SPA4. The low reflective layer 190 may be configured to correspond to the second sub-pixel 12b among a plurality of sub-pixels 12a, 12b, 12c, and 12d. The low reflective layer 190 may be patterned to correspond to the second sub-pixel 12b among a plurality of sub-pixels 12a, 12b, 12c, and 12d. Thus, the low reflective layer 190 is disposed in the second sub-pixel 12b, but not the first, third, and fourth sub-pixels 12a, 12c, and 12d. The second sub-pixel 12b among a plurality of sub-pixels 12a, 12b, 12c, and 12d may be a white sub-pixel. The low reflective layer 190 may be configured to correspond to the white sub-pixel. The low reflective layer 190 may be configured to be positioned between the second data line DL2 and the reference voltage line RL adjacent to the white sub-pixel in a plan view of the display device. According to an embodiment, the low reflective layer 190 may overlap the second data line DL2 and the reference voltage line RL adjacent to the white sub-pixel. According to another example, the low reflective layer 190 may not overlap the second data line DL2 and the reference voltage line RL adjacent to the white sub-pixel.

The low reflective layer 190 may be configured between the planarization layer 140 and the first electrode AE. The lower surface of the low reflective layer 190 may be in contact with the upper surface of the planarization layer 140. The upper surface of the low reflective layer 190 may be covered by the first electrode AE. The low reflective layer 190 may overlap the first electrode AE of the white sub-pixel. The low reflective layer 190 may overlap the light absorbing layer 180.

The low reflective layer 190 may include a conductive material. For example, the low reflective layer 190 may include molybdenum-titanium (MoTi). For example, the thickness of the low reflective layer 190 may be 60 Å or less. Accordingly, the low reflective layer 190 according to another embodiment of the present disclosure may be a semi-transmissive layer or a semi-transmissive film. Thus, the low reflective layer is semi-transmissive. For example, the thickness of the low reflective layer 190 may be implemented from 0 Å to 100 Å. However, as the thickness of the low reflective layer 190 increases, a color difference (or a color viewing angle) may increase. For example, as the low reflective layer 190 increases, a color viewing angle may be shifted. Accordingly, the thickness of the low reflective layer 190 may be optimized to 60 Å.

The area or size of the low reflective layer 190 may be smaller than that of the white sub-pixel. For example, the area of the low reflective layer 190 may be 20% or less of the area of the white sub-pixel. For example, when the area of the low reflective layer 190 exceeds 20% of the area of the white sub-pixel, the color viewing angle may be shifted.

According to another embodiment of the present disclosure, low reflection in the white sub-pixel may be achieved by configuring the low reflective layer 190 below the first electrode AE, such that it overlaps with the first electrode AE of the white sub-pixel.

Accordingly, in the light emitting display apparatus according to another embodiment of the present disclosure, reflection by external light may be further reduced, and visibility of the light emitting display apparatus may be further improved.

The light emitting display apparatus according to another embodiment of the present disclosure may not require an additional process for preventing reflection of external light after manufacturing the display panel. Accordingly, the manufacturing process of the light emitting display apparatus may be unified, and there is an effect of uni materialization.

In another embodiment of the present disclosure, another embodiment of the present disclosure was described by taking as an example that the low reflective layer 190 was additionally configured in the light emitting display apparatus described with reference to FIG. 4, and the low reflective layer 190 having the same structure and effect may be configured in the light emitting display apparatus described with reference to FIG. 3.

The light emitting display apparatus according to another embodiment of the present disclosure may further include the color control layer described with reference to FIGS. 8 and 9. A configuration and an effect of the color control layer may be the same as those of the color control layer described with reference to FIGS. 8 and 9. According to an example, the color control layer overlaps the low reflective layer 190 and may be configured to correspond to the entire surface of the white sub-pixel. According to another example, the color control layer may be configured in the remaining area of the white sub-pixel other than the area in which the low reflective layer 190 is configured. For example, the color control layer may not overlap the low reflective layer 190. The area or size of the color control layer may be set according to the size of the low reflective layer 190.

FIG. 16 is a cross-sectional view along line III-III′ shown in FIG. 14 according to another embodiment. This is where a low reflective layer is additionally configured in the light emitting apparatus shown in FIG. 6, a configuration of the low reflective layer is the same as that of the low reflective layer described with reference to FIGS. 14 and 15. Accordingly, hereinafter, the low reflective layer and the related configuration will be described, the remaining configurations will be given the same reference numerals as in FIGS. 6, 13, and 14, and redundant descriptions thereof will be simply described or omitted.

Referring to FIG. 16, a light emitting display apparatus according to another embodiment of the present disclosure may include a low reflective layer 190. The low reflective layer 190 may be patterned to correspond to the white sub-pixel. The low reflective layer 190 may be configured between the planarization layer 140 and the first electrode AE. The low reflective layer 190 may overlap the first electrode AE of the white sub-pixel.

The low reflective layer 190 may be configured under the light absorbing layer 180. The low reflective layer 190 may primarily absorb reflection of external light. External light transmitted to the low reflective layer 190 and the first electrode AE may be secondarily absorbed by the light absorbing layer 180. The light-absorbing layer 180 may have the same configuration and effect as those of the light-absorbing layer 180 of FIG. 6 where the light-absorbing layer 181 has a first light-absorbing layer 181 and a second light-absorbing layer 183. The low reflective layer 190 may have the same configuration and effect as those of the low reflective layer 190 described with reference to FIGS. 14 and 15.

According to another embodiment of the present disclosure, the low reflective layer 190 is configured under the first electrode AE to overlap the first electrode AE of the white sub-pixel, and thus, reflectance in the white sub-pixel may be reduced. Accordingly, low reflection of the light emitting display apparatus may be implemented.

Accordingly, in the light emitting display apparatus according to another embodiment of the present disclosure, the low reflective layer 190 is configured, and thus, reflection by external light may be further reduced, and visibility of the light emitting display apparatus may be improved.

In addition, the light emitting display apparatus according to another embodiment of the present disclosure may not require an additional process for preventing reflection of external light after manufacturing the display panel. Accordingly, a manufacturing process of the light emitting display apparatus may be unified, and there is an effect of uni materialization.

In another embodiment of the present disclosure, another embodiment of the present disclosure was described by taking as an example that the low reflective layer 190 was additionally configured in the light emitting display apparatus described with reference to FIG. 6, and the low reflective layer 190 having the same structure and effect may be configured in the light emitting display apparatus described with reference to FIG. 5.

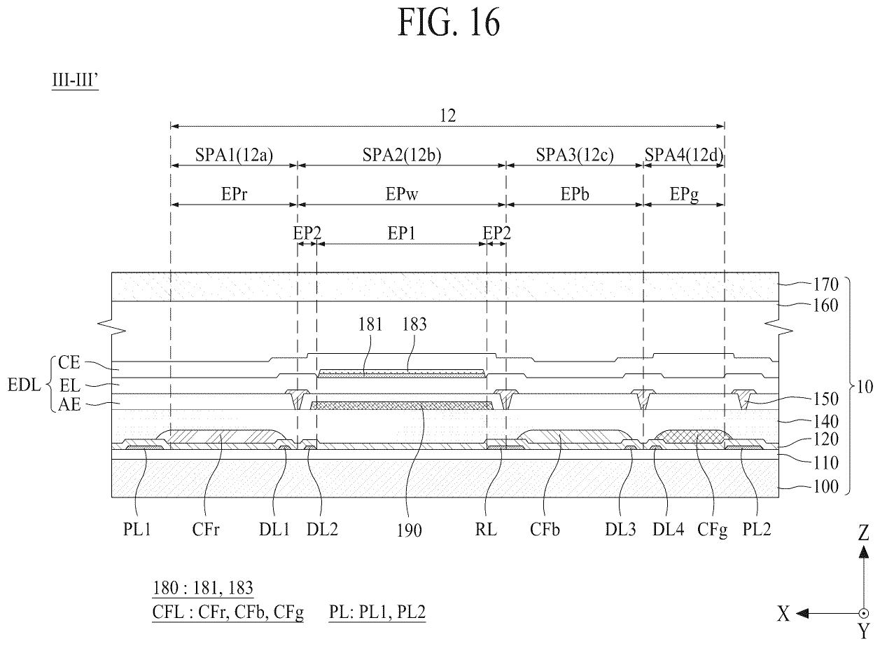

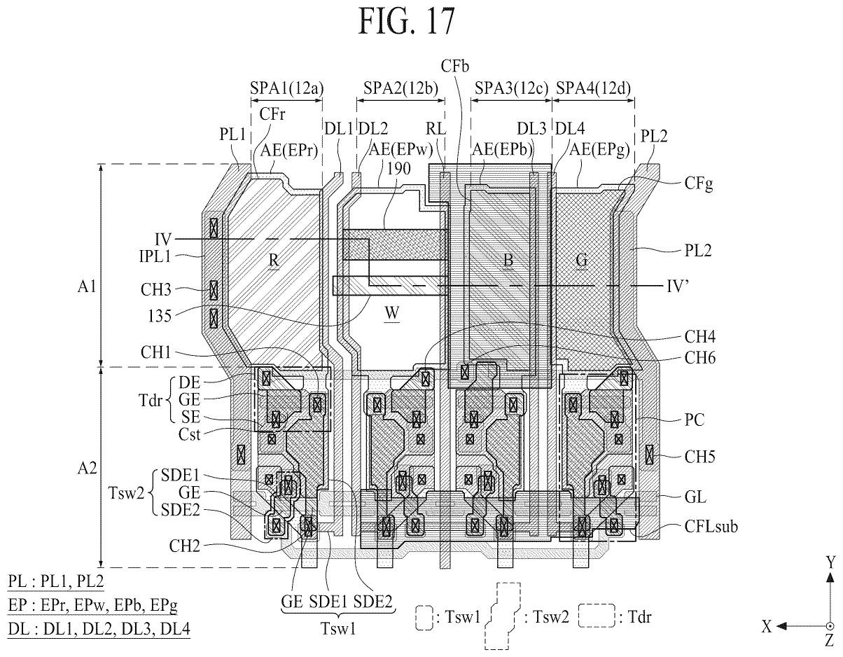

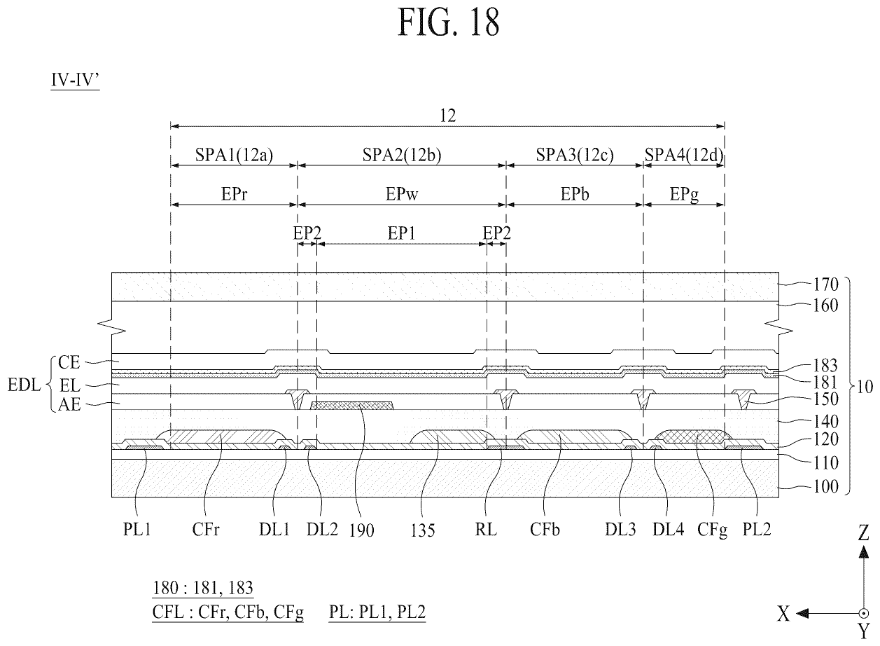

FIG. 17 is a diagram illustrating an arrangement structure of pixels illustrated in FIG. 1 according to another embodiment of the present disclosure. FIG. 18 is a cross-sectional view along line IV-IV′ shown in FIG. 17 according to one embodiment. This is where an additional auxiliary pattern portion is configured in the light emitting display apparatus shown in FIGS. 14 and 15. Accordingly, hereinafter, the auxiliary pattern portion and the related configuration will be described, the remaining configurations will be given the same reference numerals as in FIGS. 14 and 1, and redundant descriptions thereof will be simply described or omitted.

Referring to FIGS. 17 and 18, a light emitting display apparatus according to another embodiment of the present disclosure may include a light absorbing layer 180, a low reflective layer 190, and an auxiliary pattern portion 135.

The auxiliary pattern portion 135 may be configured in a second sub-pixel area SPA2 among a plurality of sub-pixel areas SPA1 to SPA4. The auxiliary pattern portion 135 may be configured to correspond to the second sub-pixel 12b among a plurality of sub-pixels 12a, 12b, 12c, and 12d. Thus, the auxiliary pattern portion 135 is disposed in the second sub-pixel area SPA2/second sub-pixel 12b. The auxiliary pattern portion 135 may be patterned to correspond to the second sub-pixel 12b among a plurality of sub-pixels 12a, 12b, 12c, and 12d. The second sub-pixel 12b among a plurality of sub-pixels 12a, 12b, 12c, and 12d may be a white sub-pixel.

The auxiliary pattern portion 135 may be configured to correspond to the white sub-pixel. Thus, the auxiliary pattern portion 135 is disposed in the white sub-pixel. The auxiliary pattern portion 135 may be configured between the second data line DL2 and the reference voltage line RL adjacent to the white sub-pixel in a plan view. The auxiliary pattern portion 135 may overlap the reference voltage line RL adjacent to the white sub-pixel without overlapping the second data line DL2. The auxiliary pattern portion 135 may overlap the reference voltage line RL adjacent to the blue sub-pixel.

The auxiliary pattern portion 135 may be non-overlapping with the low reflective layer 190 that overlaps the second data line DL2. The auxiliary pattern portion 135 may be spaced apart from the low reflective layer 190. According to an embodiment, the auxiliary pattern portion 135 and the low reflective layer 190 may be configured to be parallel to each other in the first direction X. According to another embodiment, the auxiliary pattern portion 135 and the low reflective layer 190 may be configured to be parallel to each other in the second direction Y. According to another embodiment, the auxiliary pattern portion 135 may include at least two auxiliary patterns and may be configured to be parallel to each other in the second direction Y with the low reflective layer 190 interposed therebetween. For example, when the auxiliary pattern portion 135 overlaps the low reflective layer 190, the effect of reducing the reflectance may be reduced. According to another embodiment of the present disclosure, by non-overlapping the auxiliary pattern portion 135 and the low reflective layer 190, it is possible to reduce the reflectance and improve the luminance of the white sub-pixel by improving the correlated color temperature (CCT).

The auxiliary pattern portion 135 may be configured on the same layer as the color filter layer CFL. The auxiliary pattern portion 135 may be configured between the passivation layer 120 and the planarization layer 140. The auxiliary pattern portion 135 may be covered by the planarization layer 140. The auxiliary pattern portion 135 may include the same material as the blue color filter CFb among the color filters included in the color filter layer CFL. The auxiliary pattern portion 135 may be formed by using the same process as the blue color filter CFb.

According to another embodiment of the present disclosure, as the auxiliary pattern portion 135 is configured, the color temperature of the white sub-pixel may be increased and the color coordinates of the light emitting display apparatus may be moved in a cool white direction. Accordingly, luminance of the light emitting display apparatus may be improved and reflectance of the white sub-pixel may be reduced.

According to another embodiment of the present disclosure, the auxiliary pattern portion 135 is formed using the same process as the blue color filter CFb, and thus, the auxiliary pattern portion 135 may be configured on the passivation layer 120 without an additional process.

Table 5 below evaluates reflectance and color viewing angle according to the size of the low reflective layer 190 in a light emitting display apparatus including the auxiliary pattern portion 135 and the low reflective layer 190. The size of the low reflective layer 190 means a size corresponding to the white sub-pixel. The reflectance of the low reflective layer 190 means the reflectance of the white sub-pixel.

TABLE 5

| | | Color |
|---|---|---|
| Size (%) | Reflectance | viewing angle |
| 0.0% | 58.7% | 0.0262 |
| 5.0% | 56.3% | 0.0246 |
| 10.0% | 51.6% | 0.0252 |
| 15.0% | 45.2% | 0.0258 |
| 20.0% | 37.7% | 0.0265 |
| 25.0% | 29.9% | 0.0273 |
| 30.0% | 22.5% | 0.0280 |

Referring to Table 5, the size of the low reflective layer 190 may be 20% or less of the white pixel area. For example, the size of the low reflective layer 190 may be optimized to 20% of the area of the white sub-pixel in consideration of a color viewing angle. For example, with respect to the viewing angle of the white sub-pixel, the required specification may range from 0.024 to 0.026. Accordingly, the size of the low reflective layer 190 that satisfies the required specification may be 20% of the area of the white sub-pixel. For example, when the size of the low reflective layer exceeds 20% of the white sub-pixel area, the color viewing angle in the white sub-pixel area may decrease. However, the embodiment of the present disclosure is not necessarily limited thereto.

Table 6 below shows the reflectance and luminance according to the size of the auxiliary pattern portion 135 in a light emitting display apparatus including the auxiliary pattern portion 135 and the low reflective layer 190. The size of the auxiliary pattern portion 135 means the size corresponding to the white sub-pixel. The reflectance of the auxiliary pattern portion 135 means the reflectance of the white sub-pixel.

TABLE 6

| Size (%) | Reflectance | Luminance |
|---|---|---|
| 0.0% | 17.2% | 213.3 |
| 15% | 16.0% | 272.8 |
| 20% | 15.6% | 262.2 |
| 25% | 15.2% | 195.4 |
| 30% | 14.9% | 174.5 |
| 35% | 14.6% | 168.3 |

Referring to Table 6, the size of the auxiliary pattern portion 135 may range from 15% to 20% of the white pixel area in consideration of reflectance and luminance. For example, when the size of the auxiliary pattern portion 135 is less than 15% or more than 20% of the area of the white sub-pixel, the luminance may be reduced. For example, when the size of the auxiliary pattern portion 135 exceeds 20% of the area of the white sub-pixel, the reflectance may be reduced. Accordingly, the size of the auxiliary pattern portion 135 may be optimized in the range of 15% to 20% of the white pixel area in consideration of reflectance and luminance.

The following Tables 7 to 9 show the color temperature (CCT), reflectance, and luminance of the light emitting display apparatus including the low reflective layer 190 and the auxiliary pattern portion 135, respectively. Reflectance means panel reflectance and represents reflectance of white sub-pixels. Efficiency and luminance represent efficiency and luminance of white sub-pixels.

TABLE 7

| The color | | The thin film thickness of the first | | | | |
|---|---|---|---|---|---|---|
| temperature | | light absorbing layer (Å) | | | | |
| (CCT) | | 0 Å | 50 Å | 100 Å | 150 Å | 200 Å |
| The | 0 Å | 14688.35 | 12520.86 | 11120.62 | 10294.32 | 9848.81 |
| thin | 50 Å | 11370.29 | 9910.05 | 9156.27 | 8820.08 | 8712.81 |
| film | 100 Å | 9543.06 | 8853.56 | 8632.55 | 8646.96 | 8760.38 |
| thick- | 150 Å | 8881.78 | 8795.80 | 8965.70 | 9219.95 | 9468.05 |
| ness | 200 Å | 9028.30 | 9378.10 | 9803.81 | 10186.45 | 10482.24 |
| of the | | | | | | |
| second | | | | | | |
| light | | | | | | |
| absor- | | | | | | |
| bing | | | | | | |
| layer | | | | | | |
| (Å) | | | | | | |

Referring to Table 7, the first light absorbing layer 181 shows a lower color temperature as the thickness increases from 0 Å to 200 Å, and the lowest color temperature is shown when the thickness is 200 Å. The second light absorbing layer 183 shows a lower color temperature as the thickness increases from 0 Å to 200 Å, and the lowest color temperature is shown when the thickness is 200 Å. For example, a higher color temperature represents a cool white color, and a lower color temperature represents a warm white color. For example, the target color temperature (CCT) of the TV product is approximately 10,000K, and the closer the target color temperature is, the more advantageous it may be for improving luminance.

According to an embodiment of the present disclosure, when the thicknesses of each of the first light absorbing layer 181 and the second light absorbing layer 183 are 50 Å, it shows the value closest to the target color temperature (CCT).

TABLE 8

| | | The thin film thickness of the first | | | | |
|---|---|---|---|---|---|---|
| | | light absorbing layer (Å) | | | | |
| Reflectance | | 0 Å | 50 Å | 100 Å | 150 Å | 200 Å |
| The thin | 0 Å | 72.8% | 45.4% | 41.0% | 36.7% | 33.2% |
| film | 50 Å | 41.1% | 35.0% | 29.7% | 25.7% | 22.9% |
| thickness | 100 Å | 31.4% | 25.1% | 20.7% | 17.9% | 16.2% |
| of the | 150 Å | 22.7% | 18.0% | 15.1% | 13.5% | 12.7% |
| second | 200 Å | 16.7% | 13.8% | 12.3% | 11.6% | 11.3% |
| light | | | | | | |
| absorbing | | | | | | |
| layer(Å) | | | | | | |

Referring to Table 8, the first light absorbing layer 181 showed lower reflectance as the thickness increased from 0 Å to 200 Å and showed the lowest reflectance when the thickness was 200 Å. The second light absorbing layer 183 showed lower reflectance as the thickness increased from 0 Å to 200 Å and showed the lowest reflectance when the thickness was 200 Å.

TABLE 9

| | | The thin film thickness of the first | | | | |
|---|---|---|---|---|---|---|
| | | light absorbing layer (Å) | | | | |
| Luminance | | 0 Å | 50 Å | 100 Å | 150 Å | 200 Å |
| The thin | 0 Å | 142.52 | 209.85 | 256.78 | 303.64 | 309.56 |
| film | 50 Å | 244.37 | 314.47 | 290.58 | 282.64 | 282.54 |
| thickness | 100 Å | 305.56 | 284.55 | 278.81 | 282.18 | 289.44 |
| of the | 150 Å | 286.40 | 286.68 | 294.90 | 307.49 | 321.35 |
| second | 200 Å | 294.82 | 311.90 | 333.81 | 354.93 | 374.73 |
| light | | | | | | |
| absorbing | | | | | | |
| layer(Å) | | | | | | |

Referring to Table 9, the first light absorbing layer 181 shows higher luminance as the thickness increases from 0 Å to 200 Å, and the second light absorbing layer 183 shows the highest luminance at 100 Å. According to an embodiment of the present disclosure, when the thicknesses of each of the first light absorbing layer 181 and the second light absorbing layer 183 are 50 Å, the luminance is 300 or more.

When the light emitting display apparatus includes a low reflective layer 190 and an auxiliary pattern portion 135, thicknesses of the first light absorbing layer and the second light absorbing layer 181 and 182 may be set as reference to Tables 7 to 9. Referring to Tables 7 to 9, thicknesses of the first light absorbing layer and the second light absorbing layer 181 and 182 may be set to 100 Å or less, respectively.

Referring to Tables 7 to 9, when the thicknesses of each of the first light absorbing layer 181 and the second light absorbing layer 183 are 50 Å, the color temperature is closest to the target color temperature CCT, the luminance is 300 or more, and the reflectance is 35% or less. Therefore, the thicknesses of each of the first and second light absorbing layers 181 and 182 may be optimized to 50 Å.

According to another embodiment of the present disclosure, the low reflective layer 190 is configured under the first electrode AE to overlap the first electrode AE of the white sub-pixel, and the auxiliary pattern portion 135 is configured to overlap the low reflective layer 190, and thus, the light emitting display apparatus can implement low-reflection in the white sub-pixel and be improved the luminance of the white sub-pixel.

Accordingly, reflection by external light may be further reduced in the light emitting display apparatus according to another embodiment of the present disclosure, and visibility of the light emitting display apparatus may be further improved.

In addition, the light emitting display apparatus according to another embodiment of the present disclosure may not require an additional process for preventing reflection of external light after manufacturing the display panel. Accordingly, a manufacturing process of the light emitting display apparatus may be unified, and there is an effect of uni materialization.

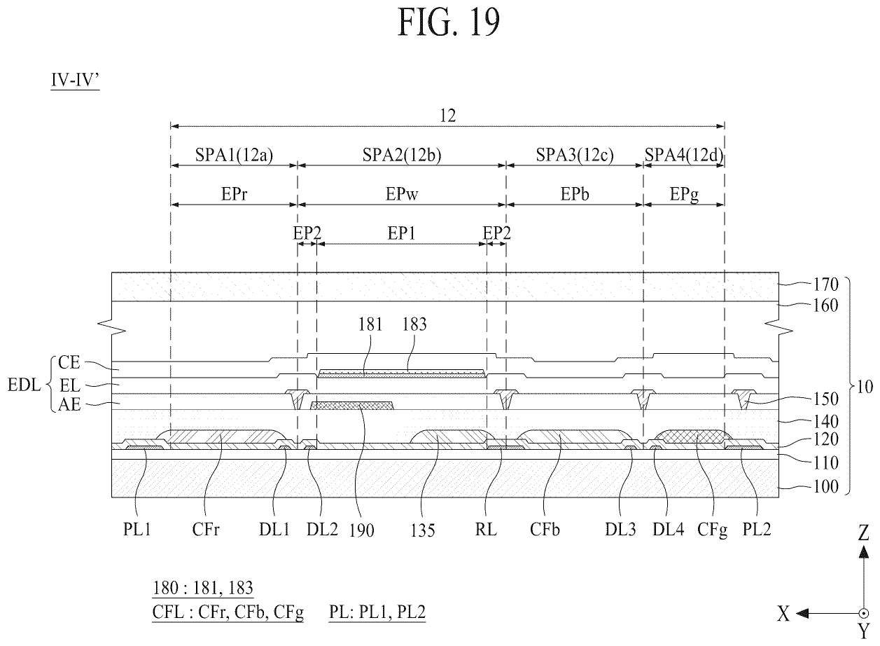

FIG. 19 is a cross-sectional view along line IV-IV′ shown in FIG. 18 according to another embodiment. This is where an additional auxiliary pattern portion is configured in the light emitting display apparatus shown in FIG. 16. Accordingly, hereinafter, the auxiliary pattern portion and the related configuration will be described, the remaining configurations will be given the same reference numerals as in FIG. 16, and redundant descriptions thereof will be simply described or omitted.

Referring to FIG. 19, a light emitting display apparatus according to another embodiment of the present disclosure may further include a light absorbing layer 180, a low reflective layer 190, and an auxiliary pattern portion 135. A configuration of the light absorbing layer 180, the low reflective layer 190, and the auxiliary pattern portion 135 may have the same configuration and effect as those of the light absorbing layer 180, the low reflective layer 190, and the auxiliary pattern portion 135 described with reference to FIG. 15.

According to another embodiment of the present disclosure, the light absorbing layer 180, the low reflective layer 190, and the auxiliary pattern portion 135 may be configured in the second sub-pixel area SPA2 among a plurality of sub-pixel areas SPA1 to SPA4. The light absorbing layer 180, the low reflective layer 190, and the auxiliary pattern portion 135 may be patterned to correspond to the second sub-pixel 12b among a plurality of sub-pixels 12a, 12b, 12c, and 12d. The light absorbing layer 180, the low reflective layer 190, and the auxiliary pattern portion 135 may be configured to correspond to the white sub-pixel.

The auxiliary pattern portion 135 may overlap the light absorbing layer 180. The auxiliary pattern portion 135 may not overlap the low reflective layer 190. The auxiliary pattern portion 135 may be configured on the same layer as the color filter layer CFL. The auxiliary pattern portion 135 may include the same material as the blue color filter CFb among the color filters included in the color filter layer CFL.

According to another embodiment of the present disclosure, the low reflective layer 190 is configured below the first electrode AE to overlap the first electrode AE of the white sub-pixel, and the auxiliary pattern portion 135 is configured to overlap the low reflective layer 190, and thus, the light emitting display apparatus can implement low-reflection in the white sub-pixel and be improved the luminance of the white sub-pixel.

Accordingly, reflection by external light may be further reduced in the light emitting display apparatus according to another embodiment of the present disclosure, and visibility of the light emitting display apparatus may be further improved.

In addition, the light emitting display apparatus according to another embodiment of the present disclosure may not require an additional process for preventing reflection of external light after manufacturing the display panel. Accordingly, a manufacturing process of the light emitting display apparatus may be unified, and there is an effect of uni materialization.

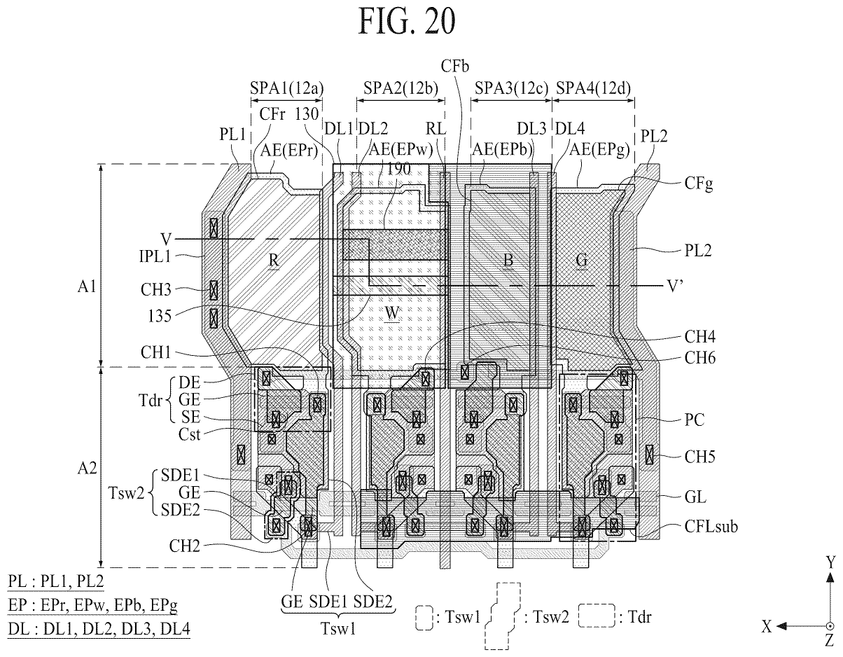

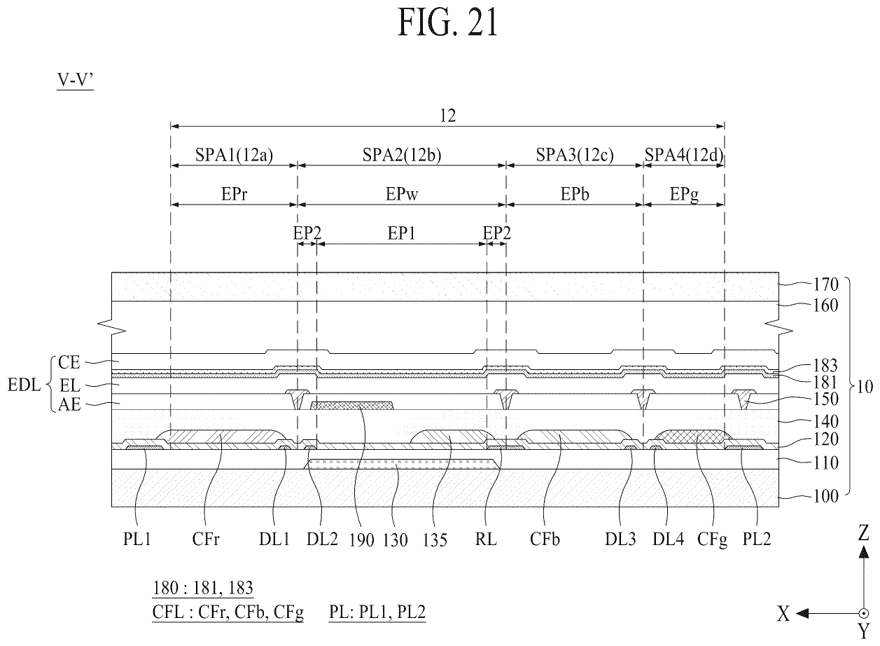

FIG. 20 is a diagram illustrating an arrangement structure of pixels illustrated in FIG. 1 according to another embodiment of the present disclosure. FIG. 21 is a cross-sectional view along line V-V′ shown in FIG. 20 according to another embodiment. This is where the color control layer is additionally configured in the light-emitting display device shown in FIGS. 17 and 18. Accordingly, hereinafter, the color control layer and the related configuration will be described, the remaining configurations will be given the same reference numerals as in FIGS. 8, 9, 17, and 18, and redundant descriptions thereof will be simply described or omitted.

Referring to FIGS. 20 and 21, a light emitting display apparatus according to another embodiment of the present disclosure may include a light absorbing layer 180, a low reflective layer 190, an auxiliary pattern portion 135, and a color control layer 130. The configuration of the light absorbing layer 180, the low reflective layer 190, and the auxiliary pattern portion 135 may have the same configuration and effect as those of the light emitting display apparatus described with reference to FIGS. 17 and 18. The configuration of the color control layer 130 may have the same configuration and effect as those of the color control layer 130 described with reference to FIGS. 8 and 9.

According to another embodiment of the present disclosure, the light absorbing layer 180, the low reflective layer 190, the auxiliary pattern portion 135, and the color control layer 130 may be configured in the second sub-pixel area SPA2 among a plurality of sub-pixel areas SPA1 to SPA4. The light absorbing layer 180, the low reflective layer 190, the auxiliary pattern portion 135, and the color control layer 130 may be patterned to correspond to the second sub-pixel 12b among a plurality of sub-pixels 12a, 12b, 12c, and 12d. The light absorbing layer 180, the low reflective layer 190, the auxiliary pattern portion 135, and the color control layer 130 may be configured to correspond to the white sub-pixel. The light absorbing layer 180 may overlap the low reflective layer 190, the auxiliary pattern portion 135, and the color control layer 130. The low reflective layer 190 and the auxiliary pattern portion 135 may not overlap.

The color control layer 130 may be configured between the substrate 100 and the buffer layer 110. According to an embodiment, the color control layer overlaps the low reflective layer 190 and the auxiliary pattern portion 135 and may be configured to correspond to the entire surface of the white sub-pixel.

According to another example, the color control layer 130 may be configured in an area of the white sub-pixel other than an area of the auxiliary pattern portion 135. For example, the color control layer 130 may overlap the low reflective layer 190 and may not overlap the auxiliary pattern portion 135. For example, the auxiliary pattern portion 135 may be configured in an area corresponding to 15% of the white pixel area, and the color control layer 130 may be configured in an area corresponding to 85% of the white pixel area.

According to another example, the color control layer 130 may be configured in the remaining area of the white sub-pixel other than a portion where the low reflective layer 190 and the auxiliary pattern portion 135 are configured. For example, the color control layer 130 may not overlap the low reflective layer 190 and the auxiliary pattern portion 190. The area or size of the color control layer 130 may be set according to the sizes of the low reflective layer 190 and the auxiliary pattern portion 190. For example, the low reflective layer 190 may be configured in an area corresponding to 20% of the white pixel area, the auxiliary pattern portion 190 may be configured in an area corresponding to 15% of the white pixel area, and the color control layer 130 may be configured in an area corresponding to 65% of the white pixel area.

According to another embodiment of the present disclosure, the color control layer 130 is configured between the substrate 100 and the buffer layer 110, and thus, in the white sub-pixel, the color or reflectance spectrum of light, which is partially absorbed by the optical absorption layer (180), reflected by the second electrode (CE), and then emitted outward, can be controlled.

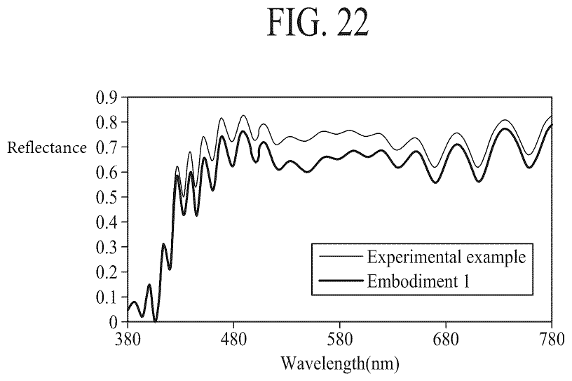

FIG. 22 is a diagram showing reflectance according to experimental example and embodiments of the present disclosure.

The inventors of the present disclosure prepared samples according to the experimental example and embodiment 1 to measure the reflectance of a light emitting display apparatus according to the embodiment of the present disclosure. In FIG. 22, the experimental example may be a light emitting display apparatus in which a light absorbing layer is not configured, and the embodiment 1 may be a light emitting display apparatus according to the embodiment of the present disclosure described with reference to FIG. 3. In FIG. 22, the reflectance may mean the panel reflectance of the white sub-pixel. The panel reflectance Σ represents the material reflectance per area multiplied by the area ratio occupied by the region within a single pixel. In FIG. 21, the solid line and the thick solid line represent the measured values for the experimental example and embodiment 1, respectively.

Referring to FIG. 22, the reflectance of each of experimental example and embodiment 1 at a wavelength of 550 nm was measured to be 78.7% and 67.7%. Accordingly, compared with the experimental example, it was found that the reflectance in embodiment 1 decreased by 11%.

Accordingly, in the light emitting display apparatus according to the embodiment of the present disclosure, the light absorbing layer is configured under the second electrode (or the cathode electrode), and thus, the reflectance in the white sub-pixel is reduced.

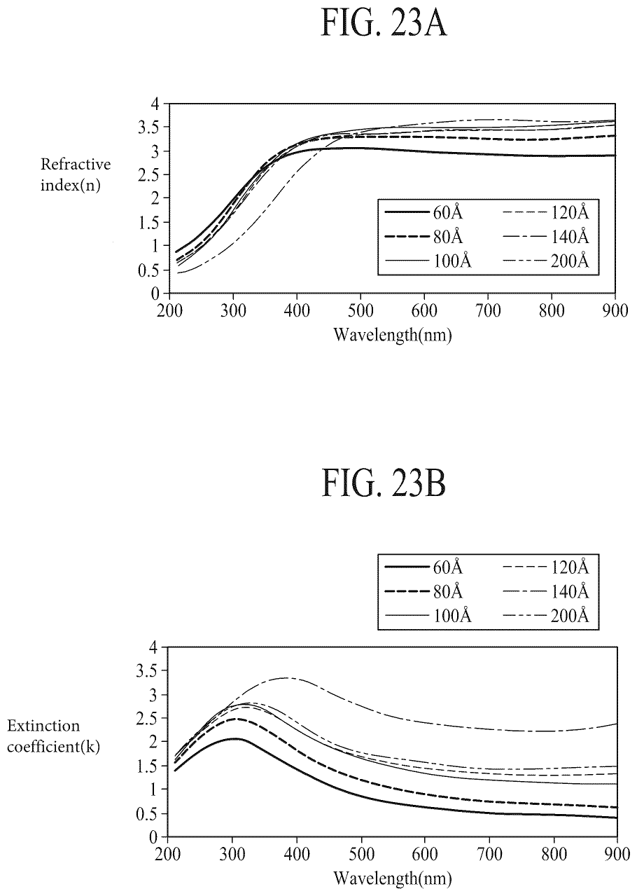

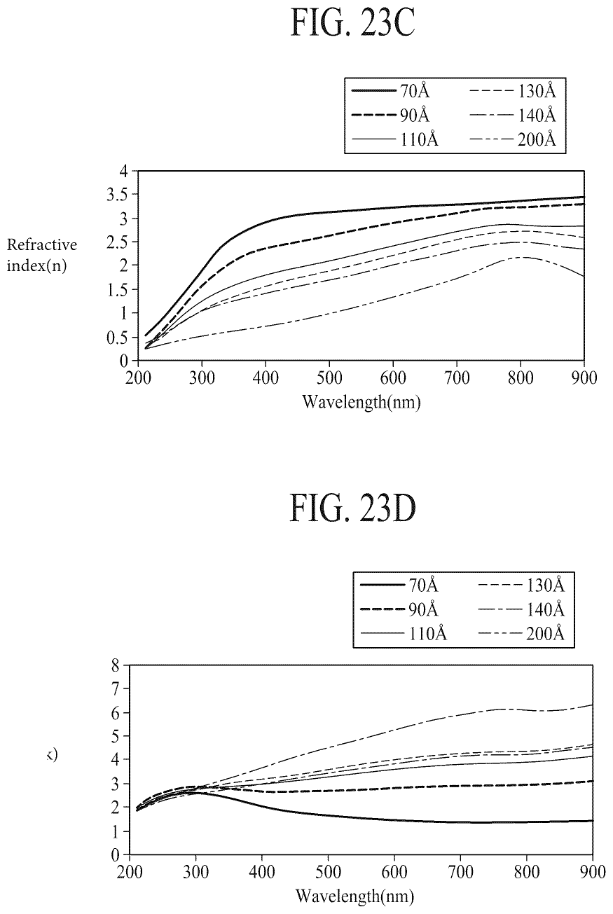

FIGS. 23A to 23D are diagrams showing refractive indices according to the deposition rate of the light absorbing layer. FIGS. 23A and 23B illustrate a refractive index n of the first light absorbing layer and a light absorption coefficient k, and FIGS. 23C and 23D illustrate a refractive index n of the second light absorbing layer and a light absorption coefficient k. The refractive index (n) represents the degree to which light is refracted in the first and second optical absorption layers. The light absorption coefficient (k) represents the degree to which light is absorbed.

The inventors of the present disclosure prepared samples according to embodiment 2 and 3 in order to find out a refractive index and a degree of light absorption according to a deposition speed and a thickness of the light absorbing layer according to embodiments of the present disclosure. The embodiment 2, like the first light absorbing layer, prepared samples by depositing an Al thin film with a deposition rate of 1.75 Å/s for each thickness. The embodiment 3, like the second light absorbing layer, prepared samples by depositing an Al thin film with a deposition rate of 3.5 Å/s for each thickness. In FIGS. 23A to 23D, a horizontal axis is a wavelength and a vertical axis is a refractive index or an absorption coefficient. In FIGS. 23A and 23B, the thick solid line, thick dashed line, solid line, dashed line, single dash-dotted line, and double dash-dotted line represent the measured values for the first light absorbing layer thicknesses of 60 Å, 80 Å, 100 Å, 120 Å, 140 Å, and 200 Å, respectively. In FIGS. 23C and 23D, the thick solid line, thick dashed line, solid line, dashed line, single dash-dotted line, and double dash-dotted line represent the measured values for the second light absorbing layer thicknesses of 70 Å, 90 Å, 110 Å, 130 Å, 140 Å, and 200 Å, respectively.

Referring to FIG. 23A, at a wavelength of 550 nm, refractive indices (n) according to thicknesses of the first light absorbing layer of 60 Å, 80 Å, 100 Å, 120 Å, 140 Å, and 200 Å showed similar values as 3.0, 3.3, 3.5, 3.4, 3.4, and 3.5, respectively. Accordingly, at a wavelength of 500 nm, it was found that the refractive index (n) does not show significant differences according to the thickness of the first light absorbing layer.

Referring to FIG. 23B, at a wavelength of 500 nm, the absorption coefficients k according to the thicknesses of the first light absorbing layer of 60 Å, 80 Å, 100 Å, 120 Å, 140 Å, and 200 Å tend to increase to 0.7, 1.0, 1.5, 1.6, and 2.5, respectively. Accordingly, it may be confirmed that the absorption coefficients k according to the thicknesses of the first light absorbing layer increase as the thicknesses of 60 Å, 80 Å, 100 Å, 100 Å, 120 Å, 140 Å, and 200 Å increase. As the absorption coefficient k increases, the reflectance may increase. Accordingly, it may be confirmed that the reflectance decreases as the thickness of the first light absorbing layer decreases.

Referring to FIG. 23C, at a wavelength of 500 nm, the refractive indices n according to the thicknesses 70 Å, 90 Å, 110 Å, 130 Å, 140 Å, and 200 Å of the second light absorbing layer tend to decrease to 3.2, 2.8, 2.3, 2.0, 1.8, and 1.2, respectively. The refractive indices n according to the thicknesses 70 Å, 90 Å, 110 Å, 130 Å, 140 Å, and 200 Å of the second light absorbing layer showed higher values as the thickness became thinner.

Referring to FIG. 23D, at a wavelength of 500 nm, the absorption coefficients k according to the thicknesses of the second light absorbing layer 70 Å, 90 Å, 110 Å, 130 Å, 140 Å, and 200 Å tend to increase to 1.5, 2.7, 3.4, 3.6, 3.8, and 4.9, respectively. Accordingly, it may be confirmed that the absorption coefficient k according to the thickness of the second light absorbing layer increases as the thickness increases. As the absorption coefficient k increases, the reflectance may increase. Accordingly, it may be confirmed that the reflectance decreases as the thickness of the second light absorbing layer decreases.

Referring to FIGS. 23A to 23D, it may be confirmed that the refractive index and the light absorption coefficient of each of the first light absorbing layer and the second light absorbing layer are changed according to the deposition speed and thickness of each of the first light absorbing layer and the second light absorbing layer. It may be confirmed that the reflectance of each of the first light absorbing layer and the second light absorbing layer is changed according to the refractive index and the light absorption coefficient of each of the first light absorbing layer and the second light absorbing layer.

The light emitting display apparatus according to the present disclosure may be applied to all electronic devices including a light emitting display apparatus. For example, the light emitting display apparatus according to the present disclosure may be applied to mobile devices, video phones, smart watches, watch phones, wearable devices, foldable devices, foldable devices, rollable devices, bendable devices, flexible devices, curved devices, electronic notebooks, electronic books, portable multimedia players PMPs, MP3 players, mobile medical devices, desktop PCs, laptop PCs, netbook computers, workstations, navigations, vehicle navigations, vehicle displays, televisions, wall paper display apparatus, signage devices, gaming devices, laptop devices, laptops, monitors, cameras, camcorders, and home appliances.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A light emitting display apparatus comprising:
a substrate including a plurality of unit pixels;
a buffer layer on the substrate;
a planarization layer on the buffer layer;
a light emitting device layer on the planarization layer, the light emitting device layer including a first electrode, a light emitting layer on the first electrode, and a second electrode on the light emitting layer; and
a light absorbing layer between the light emitting layer and the second electrode, the light absorbing layer absorbing external light incident on the light emitting display apparatus.

2. The light emitting display apparatus of claim 1, wherein the light absorbing layer has a thickness that is different from a thickness of the second electrode and a refractive index that is different from a refractive index of the second electrode.

3. The light emitting display apparatus of claim 1, wherein the light absorbing layer includes a same material as the second electrode.

4. The light emitting display apparatus of claim 1, wherein the light absorbing layer is semi-transmissive.

5. The light emitting display apparatus of claim 1, wherein a thickness of the light absorbing layer is in a range of 30 Å to 200 Å.

6. The light emitting display apparatus of claim 1, wherein the light absorbing layer covers an entire upper surface of the light emitting layer.

7. The light emitting display apparatus of claim 1, wherein each of the plurality of unit pixels includes a first sub-pixel that is a red sub-pixel that emits red light, a second sub-pixel that is a white sub-pixel that emits white light, a third sub-pixel that is a blue sub-pixel that emits blue light, and a fourth sub-pixel that is a green sub-pixel that emits green light,
wherein the light absorbing layer is disposed in the white sub-pixel.

8. The light emitting display apparatus of claim 1, wherein the light absorbing layer includes:
a first light absorbing layer on the light emitting layer; and
a second light absorbing layer on the first light absorbing layer,
wherein the first light absorbing layer has a refractive index that is different from a refractive index of the second light absorbing layer.

9. The light emitting display apparatus of claim 8, wherein the first light absorbing layer and the second light absorbing layer are semi-transmissive and deposited at different deposition rates.

10. The light emitting display apparatus of claim 8, wherein each of the plurality of unit pixels includes a first sub-pixel that is a red sub-pixel that emits red light, a second sub-pixel that is a white sub-pixel that emits white light, a third sub-pixel that is a blue sub-pixel that emits blue light, and a fourth sub-pixel that is a green sub-pixel that emits green light, and
wherein the first light absorbing layer and the second light absorbing layer are disposed in the white sub-pixel.

11. The light emitting display apparatus of claim 10, wherein the light absorbing layer further includes:
a third light absorbing layer overlapping any one of the first sub-pixel, the third sub-pixel, and the fourth sub-pixel and is non-overlapping with the second sub-pixel; and
a fourth light absorbing layer on the third light absorbing layer.

12. The light emitting display apparatus of claim 11, wherein a refractive index of the third light absorbing layer is different from a refractive index of the fourth light absorbing layer.

13. The light emitting display apparatus of claim 1, further comprising:
a low reflective layer between the planarization layer and the first electrode, the low reflective layer is semi-transmissive.

14. The light emitting display apparatus of claim 13, wherein the low reflective layer includes molybdenum-titanium.

15. The light emitting display apparatus of claim 13, wherein a thickness of the low reflective layer is 60 Å or less.

16. The light emitting display apparatus of claim 13, wherein each of the plurality of unit pixels includes a first sub-pixel that is a red sub-pixel that emits red light, a second sub-pixel that is a white sub-pixel that emits white light, a third sub-pixel that is a blue sub-pixel that emits blue light, and a fourth sub-pixel that is a green sub-pixel that emits green light, and
wherein the low reflective layer is disposed in the white sub-pixel.

17. The light emitting display apparatus of claim 16, further comprising:
a color filter layer between the buffer layer and the planarization layer; and
an auxiliary pattern portion on a same layer as the color filter layer and disposed in the white sub-pixel, and
wherein the auxiliary pattern portion is non-overlapping with the low reflective layer.

18. The light emitting display apparatus of claim 17, wherein the auxiliary pattern portion includes a same material as a blue color filter from a plurality of color filters included in the color filter layer.

19. The light emitting display apparatus of claim 17, further comprising:
a color control layer between the substrate and the buffer layer, the color control layer having a refractive index that is different from a refractive index of the substrate.

20. The light emitting display apparatus of claim 19, wherein the light absorbing layer, the low reflective layer, the auxiliary pattern portion, and the color control layer are disposed in the white sub-pixel.

21. The light emitting display apparatus of claim 19, wherein the color control layer overlaps the light absorbing layer.

22. The light emitting display apparatus of claim 19, wherein the color control layer overlaps the auxiliary pattern portion.

23. The light emitting display apparatus of claim 19, wherein the color control layer comprises indium gallium zinc oxide (InGaZnO₄).

24. A display device comprising:
a substrate including a unit pixel comprising a first sub-pixel that emits light of a first color and a second sub-pixel that emits light of a second color;
a buffer layer on the substrate;
a first color filter disposed in the first sub-pixel;
a planarization layer over the first color filter;
a light emitting device layer on the planarization layer, the light emitting device layer including a first electrode, a light emitting layer on the first electrode, and a second electrode on the light emitting layer; and
a light absorbing layer between the light emitting layer and the second electrode in at least the second sub-pixel, the light absorbing layer having a refractive index that is different from a refractive index of the second electrode.

25. The display device of claim 24, wherein a thickness of the light absorbing layer is different from a thickness of the second electrode.

26. The display device of claim 24, wherein an upper surface of the light absorbing layer is in direct contact with a lower surface of the second electrode.

27. The display device of claim 24, wherein the unit pixel further comprises a third sub-pixel that emits light of a third color and a fourth sub-pixel that emits light of a fourth color,
wherein the light absorbing layer is also between the light emitting layer and the second electrode in the first sub-pixel, the third sub-pixel, and the fourth sub-pixel.

28. The display device of claim 24, wherein the unit pixel further comprises a third sub-pixel that emits light of a third color and a fourth sub-pixel that emits light of a fourth color,
wherein the light absorbing layer is non-overlapping with the first sub-pixel, the third sub-pixel, and the fourth sub-pixel.

29. The display device of claim 24, wherein the light absorbing layer includes:
a first light absorbing layer on the light emitting layer; and
a second light absorbing layer on the first light absorbing layer such that the second light absorbing layer is between the second electrode and the first light absorbing layer, and
wherein the first light absorbing layer has a refractive index that is different from a refractive index of the second light absorbing layer.

30. The display device of claim 24, further comprising:
a color control layer between the substrate and the buffer layer in the second sub-pixel but not the first sub-pixel, the color control layer have a refractive index that is different from a refractive index of the substrate.

31. The display device of claim 24, further comprising:
a low reflective layer between the planarization layer and the first electrode, the low reflective layer is semi-transmissive.

32. The display device of claim 31, further comprising:
an auxiliary pattern portion on a same layer as the first color filter and disposed in the second sub-pixel, the auxiliary pattern portion non-overlapping with the low reflective layer.
